(19) United States
(12) Patent Application Publication
(10) Pub. No.: US 2025/0204221 A1
(43) Pub. Date: Jun. 19, 2025

(54) DISPLAY DEVICE AND METHOD FOR MANUFACTURING THE SAME

(71) Applicant: Samsung Display Co., Ltd., Yongin-si (KR)

(72) Inventors: HEEYEON PARK, Yongin-si (KR); YONGCHAN JU, Yongin-si (KR); JAEHEUNG HA, Yongin-si (KR); YEONGUK KIM, Yongin-si (KR); CHANGYEONG SONG, Yongin-si (KR); HYUNSUP YOON, Yongin-si (KR); Hyein JUNG, Yongin-si (KR)

(21) Appl. No.: 18/975,988

(22) Filed: Dec. 10, 2024

(30) Foreign Application Priority Data
Dec. 15, 2023 (KR) 10-2023-0183504

(51) Int. Cl. H10K 59/80; H10K 59/12; H10K 59/122; H10K 59/88; H10K 102/00

(52) U.S. Cl. CPC H10K 59/873; H10K 59/1201; H10K 59/122; H10K 59/88; H10K 2102/351

(57) ABSTRACT

A display device includes a base layer, a display element layer including a light emitting element on the base layer, an inorganic encapsulation film on the display element layer, and a barrier layer on the inorganic encapsulation film and including an inorganic polysilazane compound.

### CROSS-REFERENCE TO RELATED APPLICATION

The present application claims priority to and the benefit of Korean Patent Application No. 10-2023-0183504, filed on Dec. 15, 2023, in the Korean Intellectual Property Office, the entire disclosure of which is incorporated herein by reference.

### BACKGROUND

### 1. Field

One or more embodiments of the present disclosure relate to a display device and a method for manufacturing the display device, and for example, to a display device including to a barrier layer, and a method for manufacturing the display device.

### 2. Description of the Related Art

Display devices that provide users with images, such as televisions, mobile phones, tablet computers, computers, navigation units, and/or game consoles, may each include one or more display panels for generating and displaying desired images. These display panels may include light emitting elements that allow light emitting materials, which may include one or more suitable organic materials, in light emitting layers to emit light and thus achieve image display.

The reliability of these display devices, which is crucial (critical) for ensuring desired performance, depends on employing one or more suitable techniques to protect and seal the light emitting elements, including the organic materials that are vulnerable to oxygen and moisture, from the environment.

### SUMMARY

One or more aspects of embodiments of the present disclosure are directed toward a display device with a simplified manufacture process and improved product reliability.

One or more aspects of embodiments of the present disclosure are directed toward a method for manufacturing a display device, capable of providing a barrier layer having a sufficient thickness through printing to replace a structure of an organic encapsulation film and an upper inorganic encapsulation film, or forming a structure of an organic encapsulation film and an upper inorganic encapsulation film in the same process to simplify a manufacturing process, and also improving the reliability of the display device. In other words, the method involves either providing a barrier layer with sufficient thickness through printing to replace the structure of an organic encapsulation film and an upper inorganic encapsulation film, or forming both the organic and upper inorganic encapsulation films in the same process. This approach simplifies the manufacturing process and improves the reliability of the display device.

Additional aspects will be set forth in part in the description which follows and, in part, will be apparent from the description, or may be learned by practice of the presented embodiments.

According to one or more embodiments of the present disclosure, a display device includes a base layer, a display element layer including a light emitting element and on (e.g., arranged on) the base layer, an inorganic encapsulation film arranged on the display element layer, and a barrier layer on (e.g., arranged on) the inorganic encapsulation film and including an inorganic polysilazane compound.

In one or more embodiments, the display device may further include an organic encapsulation film between (e.g., arranged between) the inorganic encapsulation film and the barrier layer.

In one or more embodiments, the barrier layer may include an inorganic polymer layer including Si and N, or an inorganic polymer layer including Si, N, and O.

In one or more embodiments, a refractive index of the barrier layer may be in a range of about 1.53 to about 1.90.

In one or more embodiments, a refractive index of the barrier layer may gradually increase in a direction that is away from the inorganic encapsulation film.

In one or more embodiments, the barrier layer may have a thickness of about 1,000 angstrom (Å) to about 10,000 Å.

In one or more embodiments, if (e.g., when) the thickness of the barrier layer is 3,000 Å or less, the barrier layer may be a silicon nitride layer or a silicon oxynitride layer.

In one or more embodiments, the barrier layer may include a first portion adjacent to the inorganic encapsulation film, and a second portion spaced and/or apart (e.g., spaced apart or separated) from the inorganic encapsulation film, and a refractive index of the first portion may be less than a refractive index of the second portion.

In one or more embodiments, the first portion may include a silazane-based compound having a repeating unit of Formula 1, and the second portion may include a silicon nitride or a silicon oxynitride.

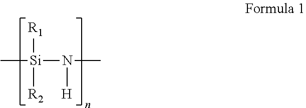

In Formula 1, R₁ and R₂ may each independently be hydrogen, an alkyl group of 1 to 10 carbon atoms, or an aryl group of 6 to 30 ring-forming carbon atoms, and n is an integer of 2 or more.

In one or more embodiments of the present disclosure, a display device includes a base layer, a pixel defining film which is on (e.g., arranged on) the base layer and in which a light emitting opening portion is defined, a partition wall which is 1 on (e.g., arranged on) the pixel defining film and in which a partition wall opening portion overlapping the light emitting opening portion is defined, a light emitting element which overlaps the light emitting opening portion and the partition wall opening portion on a plane and is on (e.g., arranged on) the base layer, an inorganic encapsulation pattern which covers the light emitting element, and a barrier layer which is on (e.g., arranged on) the inorganic encapsulation pattern and includes a polysilazane compound.

In one or more embodiments, the inorganic encapsulation pattern may have at least a portion on (e.g., arranged on) the partition wall, and cover one side surface of the partition wall, which defines the partition wall opening portion.

In one or more embodiments, the display device may further include a dummy pattern between the partition wall and the inorganic encapsulation pattern.

In one or more embodiments, the light emitting element may include a first electrode on (e.g., arranged on) the base layer, a light emitting pattern on (e.g., arranged on) the first electrode, and a second electrode on (e.g., arranged on) the light emitting pattern, and the second electrode may be electrically connected to the partition wall.

In one or more embodiments, the partition wall may include a first partition wall layer and a second partition wall layer, the partition wall opening portion may include a first region in which the light emitting element is arranged, and a second region which has a smaller width than the first region. The first partition wall layer may have a first inner side surface that defines the first region, and the second partition wall layer may have a second inner side surface that defines the second region.

In one or more embodiments, the barrier layer may include an inorganic polymer layer including Si and N, or an inorganic polymer layer including Si, N, and O, and a refractive index of the barrier layer may be in a range of about 1.53 to about 1.90.

In one or more embodiments, the barrier layer may be directly on (e.g., arranged directly on) the inorganic encapsulation pattern.

In one or more embodiments of the present disclosure, a method for manufacturing a display device includes providing a base layer, forming on the base layer a circuit layer including a conductive pattern and a plurality of insulation layers, forming on the circuit layer a display element layer including a light emitting element, forming an inorganic encapsulation layer that covers the light emitting element, and forming a barrier layer on (e.g., arranged on) the inorganic encapsulation layer and including an inorganic polysilazane compound.

### BRIEF DESCRIPTION OF DRAWINGS

The accompanying drawings are included to provide a further understanding of the disclosure, and are incorporated in and constitute a part of this disclosure. The drawings illustrate embodiments of the present disclosure and, together with the description, serve to explain principles of the disclosure. Above and/or other aspects of the present disclosure should become apparent and appreciated from the following description of embodiments taken in conjunction with the accompanying drawings. In the drawings:

FIG. 1 is a perspective view of a display device according to one or more embodiments of the present disclosure;

FIG. 2 is an exploded perspective view of a display device according to one or more embodiments of the present disclosure;

FIG. 3 is a cross-sectional view of a display module according to one or more embodiments of the present disclosure;

FIG. 4 is an enlarged plan view of a portion of a display panel according to one or more embodiments of the present disclosure;

FIGS. 5A-5C are each a cross-sectional view of a portion of a display module according to one or more embodiments of the present disclosure;

FIGS. 6A and 6B are each a cross-sectional view illustrating region AA′ in FIG. 5A;

FIGS. 7A-7C are each a schematic view illustrating one step (e.g., one act or one task) of a method for manufacturing a display device according to one or more embodiments of the present disclosure;

FIG. 8 is a schematic block diagram illustrating a step (e.g., an act or a task) of forming a barrier layer according to one or more embodiments of the present disclosure;

FIGS. 9A-9C are each a schematic view illustrating one step (e.g., one act or one task) of a method for manufacturing a display device according to one or more embodiments of the present disclosure; and

FIG. 10 is a graph illustrating results of evaluating transmittance of a barrier layer.

### DETAILED DESCRIPTION

Embodiments of the present disclosure may be modified and practiced in one or more suitable forms, and thus example embodiments thereof will be illustrated in the drawings and described herein in more detail. The disclosure should not be construed as limited to example embodiments set forth herein. Rather, these embodiments are provided so that this disclosure will be thorough and complete, and will fully convey the scope of the disclosure to those skilled in the art.

In the present disclosure, it will be understood that if (e.g., when) an element (or region, layer, section, and/or the like) is referred to as being “on,” “connected to,” or “coupled to” another element, the element may be arranged directly on, directly connected to, or directly coupled to the other element or a third element may be arranged therebetween. In contrast, when an element is referred to as being “directly on,” “directly connected to,” or “directly coupled to” another element, there are no intervening elements present therebetween.

In the present disclosure, like reference numbers or symbols refer to like elements throughout, and duplicative descriptions thereof may not be provided. In addition, in the drawings, the thickness, the ratio, and/or the dimension of elements may be exaggerated for effective description of the technical contents. The term “and/or” or “or” may include any relevant element or one or more combinations which may be defined by relevant elements.

It will be understood that, although the terms “first,” “second,” and/or the like, may be used herein to describe one or more suitable elements, these elements should not be limited by these terms. These terms are only used to distinguish one element from another element. For example, a first element could be termed a second element without departing from the teachings of the disclosure, and similarly, a second element could be termed a first element. As used herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure.”.

In addition, the terms, such as “below,” “beneath,” “on” and “above,” are used for explaining the relation of elements shown in the drawings. The terms are relative concept and are explained based on the direction shown in the drawing.

It will be further understood that the terms such as “comprise(s)/comprising,” “include(s)/including,” or “have(has)/having,” when used herein, specify the presence of stated features, numerals, steps, operations, elements, parts, or the combination thereof, but do not preclude the presence or addition of one or more other features, numerals, steps, operations, elements, parts, or the combination thereof.

As used herein, “being directly arranged” may refer to that there is no additional layer, film, region, plate and/or the like, between a part such as a layer, film, region, plate and/or the like, and another part. For example, “being directly arranged” may refer to that two layers or two members are arranged with no additional member such as an adhesive member.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display device and a method for manufacturing the display device according to one or more embodiments will be described with reference to the accompanying drawings.

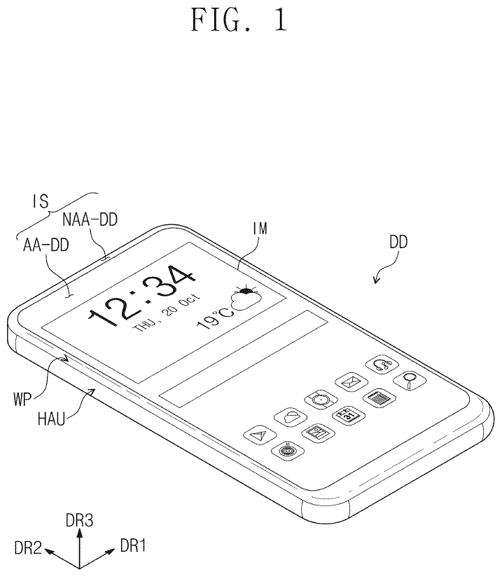

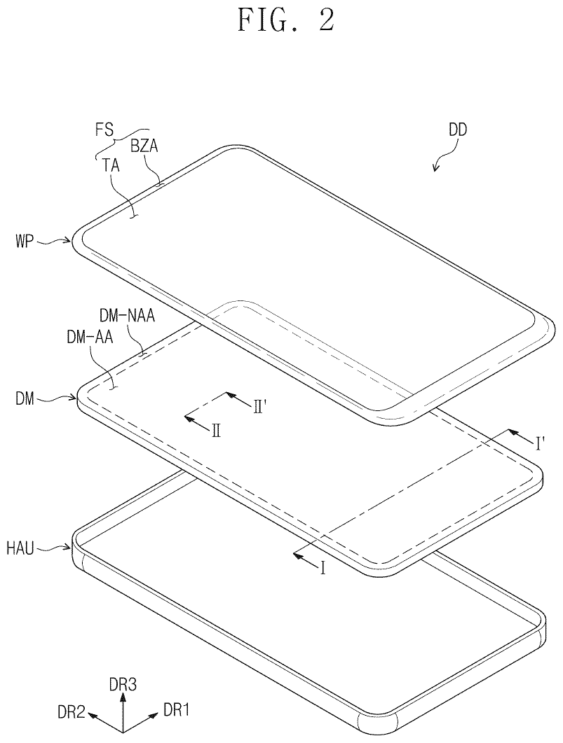

FIG. 1 is a perspective view of a display device according to one or more embodiments of the present disclosure. FIG. 2 is an exploded perspective view of a display device according to one or more embodiments of the present disclosure.

According to one or more embodiments of the present disclosure, a display device DD may be a device that is activated in response to an electrical signal and displays an image IM. The display device DD may include one or more suitable electronic devices that provide a user with an image IM. For example, the display device DD may be a large-sized device such as a television or an outdoor billboard, or may be a small or medium-sized device such as a monitor, a mobile phone, a computer, a tablet computer, a navigation device, or a game console. These embodiments of the display device DD are mere examples, and the display device DD is not limited to any one unless departing from the spirit of the disclosure. In the present disclosure, FIGS. 1 and 2 illustrate a mobile phone as an example of the display device DD.

Referring to FIG. 1, the display device DD may have a rectangular shape having short sides extending in a first direction DR1, and having long sides extending in a second direction DR2 crossing the first direction DR1 on a plane. However, embodiments of the present disclosure are not limited thereto, and the display device DD may have one or more suitable shapes such as a circular shape or a polygonal shape.

The display device DD may display an image IM in a third direction DR3 through a display surface IS parallel to a plane defined by the first direction DR1 and the second direction DR2. The third direction DR3 may be substantially parallel to a normal direction of the display surface IS. The display surface IS of the display device DD may correspond to a front surface of the display device DD.

The image IM displayed by the display device DD may include not only a dynamic image but also a still image. FIG. 1 illustrates a clock window and a plurality of icons as one example of the image IM.

In one or more embodiments, a front surface (or top surface) and a rear surface (or bottom surface) of each of members or units may be defined based on a direction in which the image IM is displayed. The front surface and the rear surface may oppose each other in the third direction DR3, and a normal direction to each of the front surface and the rear surface may be substantially parallel to the third direction DR3. A spaced distance between the front surface and the rear surface, which is defined in the third direction DR3, may correspond to a thickness of the member (or unit).

The term “on a plane” used herein may be defined as a state as viewed in the third direction DR3. The term “on a cross-section” used herein may be defined as a state as viewed in the first direction DR1 or the second direction DR2. In one or more embodiments, directions indicated by the first to third directions DR1, DR2, and DR3 are relative concepts and may be changed to other directions.

In one or more embodiments, the display device DD may be flexible. The term “flexible” refers to a characteristic of being capable of bending, and may include all from a fully folded structure to a structure capable of bending at a level of several nanometers. For example, in one or more embodiments, a flexible display device DD may be a curved device or a foldable device. However, embodiments of the present disclosure are not limited thereto, for example, in some embodiments, the display device DD may be rigid.

According to one or more embodiments of the present disclosure, FIG. 1 illustrates the display device DD having a flat display surface IS. However, the shape of the display surface IS of the display device DD is not limited thereto, for example, may be a curved shape or a three-dimensional shape.

The display surface IS of the display device DD may include a display part AA-DD and a non-display part NAA-DD. The display part AA-DD may be a part on which the image IM is displayed within the front surface of the display device DD, and a user may see the image IM through the display part AA-DD. In the embodiment shown in FIG. 1, the display part AA-DD having a rectangular shape on a plane is illustrated as an example, but the display part AA-DD may have one or more suitable shapes depending on design of the display device DD.

The non-display part NAA-DD may be a part on which the image IM is not displayed within the front surface of the display device DD. The non-display part NAA-DD may be a part which has a set or predetermined color and shields light. The non-display part NAA-DD may be adjacent to the display part AA-DD. For example, in one or more embodiments, the non-display part NAA-DD may be arranged outside the display part AA-DD to be around (e.g., surround) the display part AA-DD. However, this is illustrated as a mere example, for example, the non-display part NAA-DD may be adjacent to only one side of the display part AA-DD, or may be arranged on a side surface of the display device DD, not on the front surface. However, embodiments of the disclosure are not limited thereto, for example, in some embodiments, the non-display part NAA-DD may not be provided.

The display device DD according to one or more embodiments may detect an external input applied from the outside. The external input may include one or more suitable types (kinds) such as pressure, temperature, and light, which are provided from the outside. The external input may include not only an input by touching the display device DD (e.g., touch by the user's hand or pen) but also an input (e.g., hovering) applied by being adjacent to the display device DD.

Referring to FIGS. 1 and 2, the display device DD may include a window WP and a housing HAU. The window WP and the housing HAU may be coupled to constitute an outer appearance of the display device DD, and may provide an inner space capable of accommodating components of the display device DD. The display device DD may include a display module DM arranged between the window WP and the housing HAU. However, embodiments of the present disclosure are not limited thereto, and the display device DD may further include a light control member, an electronic module, and/or the like.

The window WP may be arranged on the display module DM. The window WP may protect the display module DM arranged underneath the window WP.

The window WP may include an optically transparent insulation material. For examples, the window WP may include glass, sapphire, plastic, and/or the like. The window WP may have a single-layer structure or a multilayer structure. In one or more embodiments, the window WP may further include functional layers, such as an anti-fingerprint layer, a phase control layer, and a hard coating layer, which are arranged on an optically transparent substrate.

A front surface FS of the window WP may correspond to the display surface IS of the display device DD described above. The front surface FS of the window WP may include a transmission region TA and a bezel region BZA.

The transmission region TA of the window WP may be an optically transparent region. For example, in one or more embodiments, the transmission region TA may be a region having a visible light transmittance of about 90% or more. The transmission region TA may correspond to the display part AA-DD of the display device DD. The transmission region TA may overlap at least a portion of an active region DM-AA of the display module DM. The window WP may be to transmit the image IM provided by the display module DM through the transmission region TA, and a user may see this image IM. In the present disclosure, an “region/portion corresponds to another region/portion” refers to that the two regions/portions “overlap each other”, but is not limited to the two regions/portions having the same surface area and/or the same shape.

The bezel region BZA of the window WP may be a region provided by depositing, coating, or printing a material having a set or predetermined color on a transparent substrate. The bezel region BZA may be a region having a relatively low light transmittance if (e.g., when) compared to the transmission region TA. The bezel region BZA may define a shape of the transmission region TA. The bezel region BZA may be adjacent to the transmission region TA and be around (e.g., surround) the transmission region TA. However, this is illustrated as a mere example, for example, in one or more embodiments, the bezel region BZA of the window WP may not be provided.

The bezel region BZA may correspond to the non-display part NAA-DD of the display device DD. The bezel region BZA may overlap at least a portion of a peripheral region DM-NAA of the display module DM. The bezel region BZA of the window WP may cover the peripheral region DM-NAA of the display module DM to prevent one component of the display module DM, which is arranged in the peripheral region DM-NAA, from being visible from the outside.

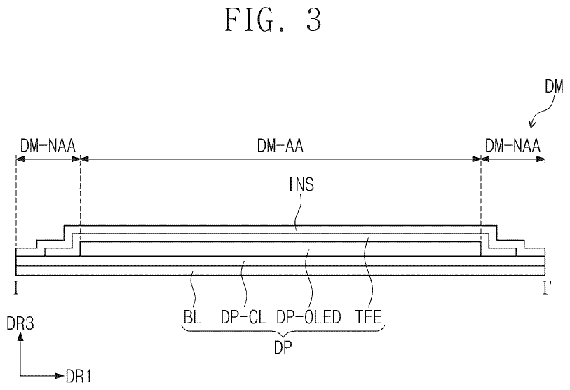

The display module DM may be arranged below/underneath the window WP. The display module DM may include a display panel DP (see FIG. 3) to be described in more detail later. The display panel DP (see FIG. 3) may generate an image in response to an electrical signal. The display panel DP (see FIG. 3) may be a light emitting display panel, but embodiments of the present disclosure are not limited thereto.

The display module DM may include the active region DM-AA, and the peripheral region DM-NAA adjacent to the active region DM-AA. The active region DM-AA may be a region that is activated in response to an electrical signal. Although not illustrated, a plurality of pixels may be arranged in the active region DM-AA.

The peripheral region DM-NAA may be around (e.g., surround) the active region DM-AA. The peripheral region DM-NAA may be a region covered by the bezel region BZA of the window WP, and may not be visible from the outside. A driving circuit or driving line for driving the pixels arranged in the active region DM-AA, one or more suitable signal lines or pads, which provide elements with electrical signals, and/or the like, may be arranged in the peripheral region DM-NAA.

In one or more embodiments, the display device DD may further include a light control member arranged between the display module DM and the window WP. In one or more embodiments, the light control member may be a reflection reduction layer that reduces reflectance of external light incident from the outside of the display device DD. However, embodiments of the present disclosure are not limited thereto, and the light control member may include one or more suitable components of a light control layer for improving display quality of the display device DD. For example, the light control member according to one or more embodiments may include a polarizing layer, a retarder, a destructive interference structure, a plurality of color filters, and/or the like.

The housing HAU may be arranged below the display module DM. The housing HAU may be coupled to the window WP. The housing HAU may be coupled to the window WP to provide a set or predetermined inner space. The display module DM may be accommodated in the inner space. The housing HAU may protect components accommodated in the housing HAU. The housing HAU may prevent or reduce foreign matters, moisture, and/or the like, from being introduced into the display module DM from the outside. The housing HAU may include a material having a relatively high rigidity, and the housing HAU may be to absorb an impact applied from the outside. In one or more embodiments, the housing HAU may be provided in a shape in which a plurality of accommodation members are coupled to each other.

FIG. 3 is a cross-sectional view of a display module according to one or more embodiments. FIG. 3 is a schematic view illustrating a cross-section corresponding to line I-I′ in FIG. 2.

Referring to FIG. 3, the display module DM according to one or more embodiments may include a display panel DP and an input sensor INS. The display panel DP may include a base layer BL, a circuit layer DP-CL, a display element layer DP-OLED, and an encapsulation layer TFE.

The base layer BL may be a member that provides a base surface on which the circuit layer DP-CL is provided and arranged. The base layer BL may be a rigid substrate, or a flexible substrate capable of being bent, folded, rolled, and/or the like. The base layer BL may be a glass substrate, a metal substrate, a silicon substrate, a polymer substrate, and/or the like. However, embodiments of the disclosure are not limited thereto, and the base layer BL may be an inorganic layer, an organic layer, or a composite material layer.

The circuit layer DP-CL may be arranged on the base layer BL. The circuit layer DP-CL may include an insulation layer, a semiconductor pattern, a conductive pattern, a signal transmission region, and/or the like. The insulation layer, a semiconductor layer, and a conductive layer may be formed on the base layer BS through a method such as coating or deposition, and then, the insulation layer, the semiconductor layer, and the conductive layer may be selectively patterned by performing a photolithography process multiple times. Thereafter, the semiconductor pattern, the conductive pattern, and the signal line (of the signal transmission region), which are included in the circuit layer DP-CL, may be provided.

The display element layer DP-OLED may be arranged on the circuit layer DP-CL. The display element layer DP-OLED may include a light emitting element. For example, the display element layer DP-OLED may include an organic light emitting material, an inorganic light emitting material, an organic-inorganic light emitting material, a quantum dot, a quantum rod, a micro LED, a nano LED, and/or the like.

The encapsulation layer TFE may be arranged on the display element layer DP-OLED. The encapsulation layer TFE may protect the display element layer DP-OLED against moisture, oxygen, and a foreign matter such as dust particles. The encapsulation layer TFE according to one or more embodiments may include a barrier layer including an inorganic polysilazane compound. The inorganic polysilazane compound may be a layer formed by polymerizing and curing a silazane-based compound.

In one or more embodiments, the barrier layer including the inorganic polysilazane compound may be a layer including Si and N, and including a silicon nitride in which Si and N are bonded to each other to form a network. In one or more embodiments, the barrier layer including the inorganic polysilazane compound may be a layer including Si, O, and N, and including a silicon oxynitride in which Si, O, and N are bonded to each other to form a network.

In one or more embodiments, the encapsulation layer TFE may include a plurality of layers, and a layer, which is spaced and/or apart (e.g., spaced apart or separated) from the display element layer DP-OLED to be arranged on the uppermost portion of the encapsulation layer TFE, of the plurality of layers may include the inorganic polysilazane compound. The encapsulation layer TFE according to one or more embodiments will be described later in more detail.

In the display module DM according to one or more embodiments, the input sensor INS may be arranged on the encapsulation layer TFE. The input sensor INS may have a multilayer structure. The input sensor INS may include a conductive layer having a single-layer structure or a multilayer structure. In addition, the input sensor INS may include an insulation layer having a single-layer or multilayer structure. In one or more embodiments, the input sensor INS may be formed on the encapsulation layer TFE through a continuous process. In these embodiments, the input sensor INS may be expressed as being arranged directly on the encapsulation layer TFE. The phrase “being arranged directly” may refer to that a third component is not arranged between the input sensor INS and the encapsulation layer TFE. For example, a separate adhesive member may not be arranged between the input sensor INS and the encapsulation layer TFE. In one or more embodiments, the input sensor INS and the encapsulation layer TFE may be coupled to each other through an adhesive member. The adhesive member may include an adhesive or adhesive agent.

The input sensor INS obtains coordinate information of an external input. In one or more embodiments, the input sensor INS may detect an external input by using a capacitance method. However, this is a mere example, and embodiments of the present disclosure are not limited thereto. For example, in one or more embodiments, the input sensor INS may detect an external input by using an electromagnetic induction method or a pressure detection method. In one or more embodiments, the input sensor INS may not be provided.

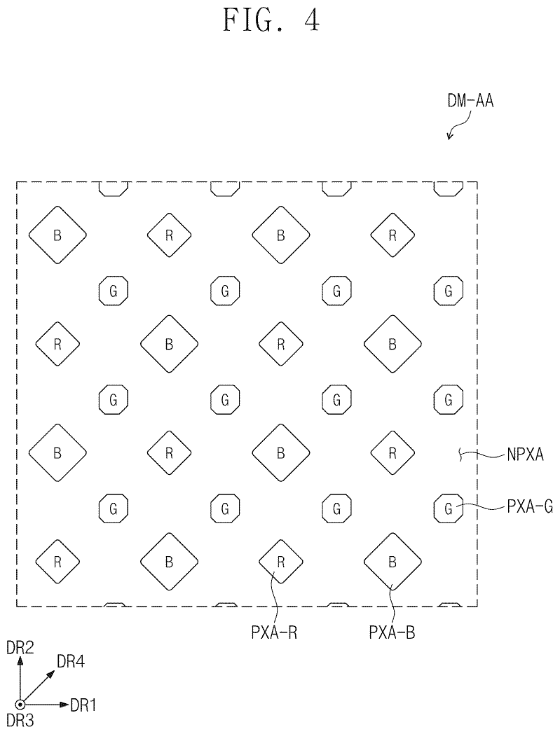

FIG. 4 is an enlarged plan view of a portion of a display panel according to one or more embodiments. FIG. 4 is an enlarged view illustrating a portion of the active region DM-AA of the display panel DP (see FIG. 3) according to one or more embodiments. In addition, FIG. 4 illustrates arrangement of light emitting regions PXA-B, PXA-G, and PXA-R in the active region DM-AA.

Referring to FIG. 4, the active region DM-AA may include first to third light emitting regions PXA-B, PXA-G, and PXA-R, and a peripheral region NPXA around (e.g., surrounding) each of the first to third light emitting regions PXA-B, PXA-G, and PXA-R. The first to third light emitting regions PXA-B, PXA-G, and PXA-R may correspond, respectively, to regions from which light provided from light emitting elements is emitted. The first to third light emitting regions PXA-B, PXA-G, and PXA-R may be divided according to colors of light emitted toward the outside of the display module DM (see FIG. 3).

The first to third light emitting regions PXA-B, PXA-G, and PXA-R may provide light having first to third colors different from each other, respectively. For example, the light having the first color may be blue light, the light having the second color may be green light, and the light having the third color may be red light. However, examples of the light having the first to third colors are not necessarily limited to the foregoing examples.

Each of the first to third light emitting regions PXA-B, PXA-G, and PXA-R may be defined as a region in which a top surface of an anode is exposed by a light emitting opening portion which will be described in more detail later. The peripheral region NPXA may set a boundary of each of the first to third light emitting regions PXA-B, PXA-G, and PXA-R, and prevent or reduce mixture of colors between the first to third light emitting regions PXA-B, PXA-G, and PXA-R.

Each of the first to third light emitting regions PXA-B, PXA-G, and PXA-R may be provided in plurality to have a set or predetermined arrangement shape and be repeatedly arranged in the active region DM-AA. For example, in one or more embodiments, the first and third light emitting regions PXA-B and PXA-R may be alternately arranged in the first direction DR1 to constitute a “first group.” The second light emitting regions PXA-G may be arranged in the first direction DR1 to constitute a “second group.” Each of the “first group” and the “second group” may be provided in plurality, and the “first group” and the “second group” may be alternately arranged in the second direction DR2.

One second light emitting region PXA-G may be arranged to be spaced and/or apart (e.g., spaced apart or separated) from one first light emitting region PXA-B or one third light emitting region PXA-R in a fourth direction DR4. The fourth direction DR4 may be defined as a direction between the first direction DR1 and second direction DR2.

FIG. 4 illustrates an example of the arrangement shape of the first to third light emitting regions PXA-B, PXA-G, and PXA-R. However, embodiments of the present disclosure are not limited thereto, and the first to third light emitting regions PXA-B, PXA-G, and PXA-R may be arranged in one or more suitable shapes. In one or more embodiments, the first to third light emitting regions PXA-B, PXA-G, and PXA-R may have a PENTILE® arrangement shape as illustrated in FIG. 4. In one or more embodiments, the first to third light emitting regions PXA-B, PXA-G, and PXA-R may have a stripe arrangement shape or a diamond (Diamond Pixel™) arrangement shape). PENTILE® is a duly registered trademark of Samsung Display Co., Ltd. Diamond Pixel™ is a trademark of Samsung Display Co., Ltd.

Each of the first to third light emitting regions PXA-B, PXA-G, and PXA-R may have one or more suitable shapes on a plane. For example, in one or more embodiments, each of the first to third light emitting regions PXA-B, PXA-G, and PXA-R may independently have a shape such as a polygonal, circular, or oval shape. According to one or more embodiments, FIG. 4 illustrates the first and third light emitting regions PXA-B and PXA-R each having a square (or rhombus) shape, and the second light emitting region PXA-G having an octagonal shape on a plane.

The first to third light emitting regions PXA-B, PXA-G, and PXA-R may have the same shape, or at least some thereof may have different shapes from each other on a plane. According to one or more embodiments, FIG. 4 illustrates the first and third light emitting regions PXA-B and PXA-R having the same shape, and the second light emitting region PXA-G having a different shape from that of the first and third emission regions PXA-B and PXA-R on a plane.

At least some selected from among the first to third light emitting regions PXA-B, PXA-G, and PXA-R may have different surface areas on a plane. In one or more embodiments, a surface area of the third light emitting region PXA-R that is configured to emit the red light may be greater than a surface area of the second light emitting region PXA-G that is configured to emit the green light, and be less than a surface area of the first light emitting region PXA-B that is configured to emit the blue light. However, a size relationship between the surface areas of the first to third light emitting regions PXA-B, PXA-G, and PXA-R according to the colors of the emitted light is not limited thereto, and may be varied according to design of the display module DM (see FIG. 3). For example, in one or more embodiments, the first to third light emitting regions PXA-B, PXA-G, and PXA-R may have the same surface area on a plane.

The shape, surface area, arrangement, and/or the like of the first to third light emitting regions PXA-B, PXA-G, and PXA-R of the display module DM (see FIG. 3) according to one or more embodiments of the disclosure may be variously designed according to the color of the emitted light or the size or configuration of the display module DM (see FIG. 2), and are not limited to one or more embodiments illustrated in FIG. 4.

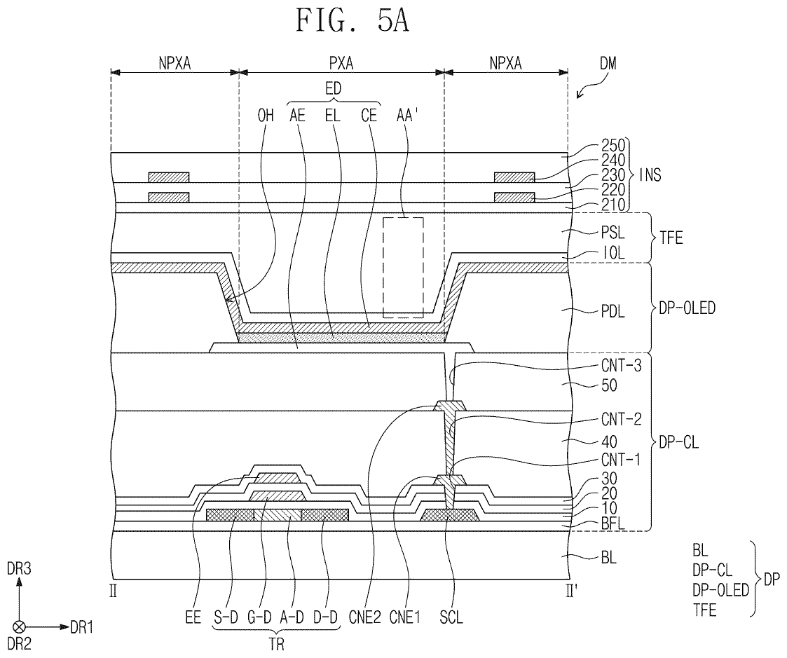

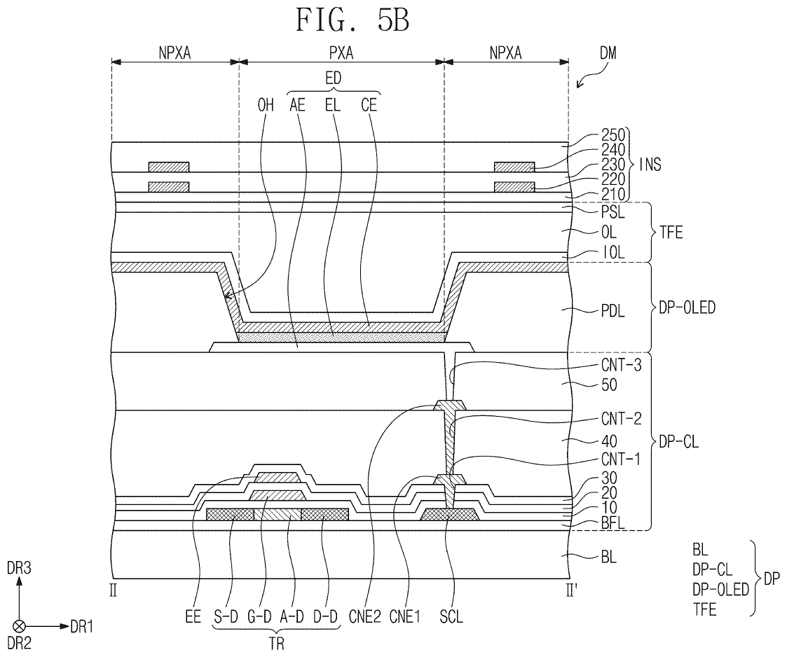

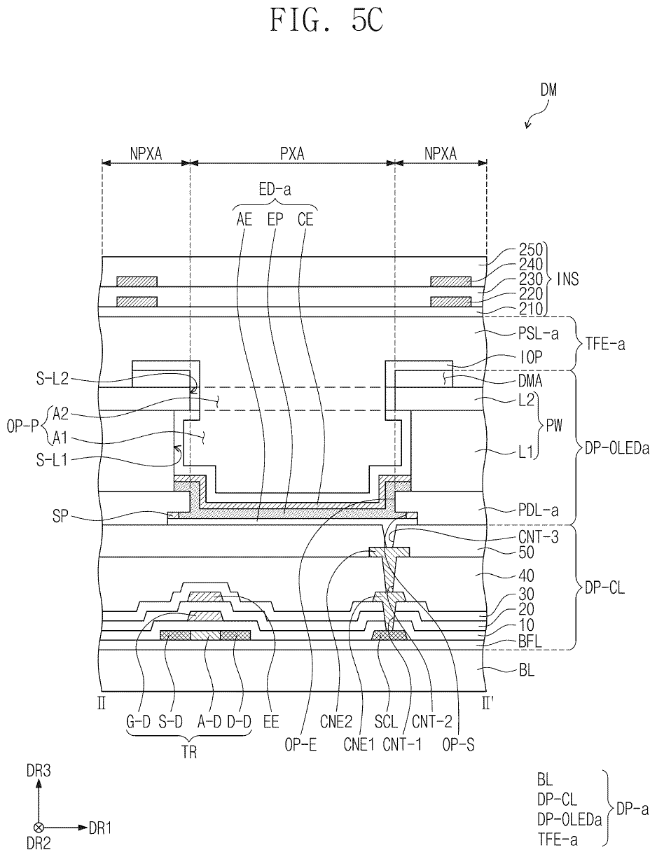

FIGS. 5A to 5C are each a cross-sectional view of a portion of a display module according to one or more embodiments. FIGS. 5A to 5C may each illustrate a portion corresponding to line II-II′ in FIG. 3. In one or more embodiments to be described with reference to FIGS. 5A to 5C, FIG. 4 is referred to, but components designated by like reference numbers or symbols may not be described for conciseness.

For example, FIGS. 5A to 5C may each illustrate a portion corresponding to one light emitting region PXA in the active region DM-AA. The light emitting region PXA illustrated in FIGS. 5A to 5C may independently correspond to any one of the first to third light emitting regions PXA-B, PXA-G, and PXA-R in FIG. 4.

Referring to FIGS. 5A to 5C, a display module DM may include a display panel DP or DP-a and an input sensor INS, and the display panel DP or DP-a may include a base layer BL, a circuit layer DP-CL, a display element layer DP-OLED or DP-OLEDa, and an encapsulation layer TFE or TFE-a. The display panel DP illustrated in FIGS. 5A and 5B may include the base layer BL, the circuit layer DP-CL, the display element layer DP-OLED, and the encapsulation layer TFE that are stacked in sequence. As an example, FIG. 5C illustrates one or more embodiments of the display panel DP illustrated in FIGS. 5A and 5B. The display panel DP-a illustrated in FIG. 5C may include the base layer BL, the circuit layer DP-CL, the display element layer DP-OLEDa, and the encapsulation layer TFE-a that are stacked in sequence.

According to one or more embodiments, FIGS. 5A and 5B each illustrate one transistor TR and a light emitting element ED, each of which corresponds to the light emitting region PXA. According to one or more embodiments, FIG. 5C illustrates one transistor TR and a light emitting element ED-a, each of which corresponds to the light emitting region PXA.

Referring to FIGS. 5A to 5C, the circuit layer DP-CL may include a buffer layer BFL, the transistor TR, a signal transmission region SCL, a plurality of insulation layers 10, 20, 30, 40 and 50, an electrode pattern EE, and a plurality of connection electrodes CNE1 and CNE2. Although not illustrated, in one or more embodiments, the circuit layer DP-CL may further include a plurality of conductive patterns. For example, in one or more embodiments, the circuit layer DP-CL may further include a plurality of transistors in addition to the transistor TR illustrated herein, a capacitor, or additional conductive patterns that constitute the connection electrode. The components of the circuit layer DP-CL illustrated in FIGS. 5A to 5C are mere examples, and the types (kinds), the number, and the arrangement positions of the conductive patterns, and the number of the insulation layers may be changed.

The buffer layer BFL may be arranged on the base layer BL. The buffer layer BFL may improve bonding force between the base layer BL and the semiconductor pattern or the conductive pattern, which are arranged on the buffer layer BFL. In addition, the buffer layer BFL may prevent or alleviate a phenomenon in which metal atoms or impurities may disperse or diffuse from the base layer BL into the semiconductor pattern or the conductive pattern.

The buffer layer BFL may be an inorganic film. The buffer layer BFL may include at least one of a silicon oxide, a silicon nitride, or a silicon oxynitride. For example, in one or more embodiments, the buffer layer BFL may include a structure in which a silicon oxide layer and a silicon nitride layer are alternately stacked. In one or more embodiments, the buffer layer BFL may not be provided.

The semiconductor pattern may be arranged on the buffer layer BFL. In one or more embodiments, the semiconductor pattern may include polysilicon. However, embodiments of the present disclosure are not limited thereto, for example, in one or more embodiments, the semiconductor pattern may include amorphous silicon or a metal oxide. FIGS. 5A to 5C just illustrate a portion of the semiconductor pattern as an example, and the semiconductor pattern may be further arranged in the plurality of light emitting regions PXA-B, PXA-G, and PXA-R. In one or more embodiments, the semiconductor pattern may be arranged over the plurality of light emitting regions PXA-B, PXA-G and PXA-R according to a specific or designed rule. The semiconductor pattern may have different electrical properties according to whether or not the semiconductor pattern is doped. The semiconductor pattern may include a first region having a high doping concentration and a second region having a low doping concentration. The first region may be doped with an n-type or kind dopant or a p-type or kind dopant. In one or more embodiments, a p-type or kind transistor may include the first region doped with the p-type or kind dopant.

The first region has higher conductivity than the second region, and substantially serves as an electrode or a signal line. The second region may substantially correspond to an active (or channel) of a transistor. For example, one portion of the semiconductor pattern may be an active of the transistor, another portion thereof may be a source or a drain of the transistor, and still another portion thereof may be a conductive region.

In one or more embodiments, the transistor TR may be arranged on the buffer layer BFL. Although not illustrated, the transistor TR may be electrically connected to the light emitting element ED or ED-a. A source S-D, an active A-D, and a drain D-D of the transistor TR may be provided from the semiconductor pattern. In addition, FIGS. 5A to 5C each illustrate a portion of the signal transmission region SCL provided from the semiconductor pattern. The signal transmission region SCL may be arranged on the buffer layer BFL. Although not separately illustrated, the signal transmission region SCL may be connected to the drain D-D of the transistor TR on a plane.

The circuit layer DP-CL may include the plurality of insulation layers 10, 20, 30, 40 and 50 that are stacked in sequence. The insulation layers 10, 20, 30, 40 and 50 may be arranged on the buffer layer BFL. Each of the insulation layers 10, 20, 30, 40 and 50 may be an inorganic layer or an organic layer. For example, in one or more embodiments, each of first to third insulation layers 10, 20 and 30 may include an inorganic film, and each of a fourth insulation layer 40 and a fifth insulation layer 50 may include an organic film. However, embodiments of the present disclosure are not limited thereto. In one or more embodiments, in the circuit layer DP-CL, at least one selected from among the first to fifth insulation layers 10, 20, 30, 40 and 50 may not be provided, or an additional insulation layer may be further included.

The first insulation layer 10 may be arranged on the buffer layer BFL. The first insulation layer 10 may include an inorganic film. The first insulation layer 10 may be referred to as a first inorganic film. For example, in one or more embodiments, the first insulation layer 10 may be an inorganic film including at least one of an aluminum oxide, a titanium oxide, a silicon oxide, a silicon nitride, a silicon oxynitride, a zirconium oxide, or a hafnium oxide. The first insulation layer 10 may have a single-layer structure or a multilayer structure. In one or more embodiments, the first insulation layer 10 may have a structure in which a plurality of inorganic films are stacked.

In one or more embodiments, the first insulation layer 10 may further include an organic film in addition to an inorganic film. When the first insulation layer 10 includes a structure in which an inorganic film and an organic film are stacked, the first insulation layer 10 may further include an inorganic buffer film arranged between the inorganic film and the organic film that are adjacent to one another.

The same as the content regarding the first insulation layer 10 described above may apply to the insulation layers to be described later, such as the second and third insulation layers 20 and 30. The second and third insulation layers 20 and 30 may be referred to as second and third inorganic films, respectively. A single-layer structure or a multilayer structure may be introduced into each of the second and third insulation layers 20 and 30. For example, in one or more embodiments, the second and third insulation layers 20 and 30 may each independently include at least one of a silicon oxide, a silicon nitride, or a silicon oxynitride.

The first insulation layer 10 may be arranged on the buffer layer BFL. The first insulation layer 10 may cover the source S-D, the active A-D, and the drain D-D of the transistor TR, and the signal transmission region SCL, which are arranged on the buffer layer BFL. A gate G-D of the transistor TR may be arranged on the first insulation layer 10. The second insulation layer 20 may be arranged on the first insulation layer 10 to cover the gate G-D. The electrode pattern EE may be arranged on the second insulation layer 20. The third insulation layer 30 may be arranged on the second insulation layer 20 to cover the electrode pattern EE.

A first connection electrode CNE1 may be arranged on the third insulation layer 30. The first connection electrode CNE1 may be connected to the signal transmitting region SCL through a first contact hole CNT-1 passing through the first to third insulation layers 10, 20 and 30. The fourth insulation layer 40 may be arranged on the third insulation layer 30 to cover the first connection electrode CNE1. The fourth insulation layer 40 may be an organic layer. The fourth insulation layer 40 may be referred to as a first organic film.

A second connection electrode CNE2 may be arranged on the fourth insulation layer 40. The second connection electrode CNE2 may be connected to the first connection electrode CNE1 through a second contact hole CNT-2 passing through the fourth insulation layer 40. The fifth insulation layer 50 may be arranged on the fourth insulation layer 40 to cover the second connection electrode CNE2. The fifth insulation layer 50 may be an organic layer. The fifth insulation layer 50 may be referred to as a second organic film.

The fourth insulation layer 40 and the fifth insulation layer 50 may each independently include at least one of acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin.

Referring to FIGS. 5A and 5B, the display element layer DP-OLED according to one or more embodiments may be arranged on the circuit layer DP-CL. The display element layer DP-OLED may include the light emitting element ED and a pixel defining film PDL. The light emitting element ED may include a first electrode AE, a second electrode CE opposite to (e.g., facing) the first electrode AE, and a functional layer EL arranged between the first electrode AE and the second electrode CE.

The first electrode AE may be arranged on the circuit layer DP-CL. In one or more embodiments, the first electrode AE may be arranged on the fifth insulation layer 50 of the circuit layer DP-CL. The first electrode AE may be connected to the second connection electrode CNE2 through a connection contact hole CNT-3 passing through and defined in the fifth insulation layer 50. Thus, the first electrode AE may be electrically connected to the signal transmission region SCL through the first and second connection electrodes CNE1 and CNE2 to be electrically connected to a corresponding circuit element. The first electrode AE may include a single-layer structure or a multilayer structure.

The first electrode AE may be an anode or a cathode. The first electrode AE may also be a pixel electrode. The second electrode CE may be a cathode or an anode. In one or more embodiments, the second electrode CE may be a common electrode. For example, if (e.g., when) the first electrode AE is an anode, the second electrode CE may be a cathode, and if (e.g., when) the first electrode AE is a cathode, the second electrode CE may be an anode.

The first electrode AE may be a transmissive electrode, a semi-transmissive electrode, or a reflective electrode. The first electrode AE may include silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), LiF/Ca, LiF/Al, molybdenum (Mo), titanium (Ti), tungsten (W), or a compound or a mixture thereof (e.g., a mixture of Ag and Mg). In one or more embodiments, the first electrode AE may have a multilayer structure including a reflective film or a semi-transmissive film, each of which is made of one or more of the foregoing materials, and a transparent conductive film which is made of an indium tin oxide (ITO), an indium zinc oxide (IZO), a zinc oxide (ZnO), an indium tin zinc oxide (ITZO), and/or the like. For example, in one or more embodiments, the first electrode AE may have a three-layer structure of ITO/Ag/ITO, but embodiments of the present disclosure are not limited thereto. In one or more embodiments, the first electrode AE may include one of the foregoing metal materials, a combination of two or more metal materials selected from among the foregoing metal materials, an oxide of the foregoing metal material, and/or the like.

The second electrode CE may be a transmissive electrode, a semi-transmissive electrode, or a reflective electrode. In one or more embodiments, when the second electrode CE is a transmissive electrode, the second electrode CE may be made of a transparent metal oxide, for example, an indium tin oxide (ITO), an indium zinc oxide (IZO), a zinc oxide (ZnO), an indium tin zinc oxide (ITZO), and/or the like. In one or more embodiments, the second electrode CE may include Ag, Mg, Cu, Al, Pt, Pd, Au, Ni, Nd, Ir, Cr, Li, Ca, LiF/Ca, LiF/Al, Mo, Ti, W, or a compound or mixture thereof (e.g., a mixture of Ag and Mg).

The functional layer EL may include a light emitting layer. The light emitting layer may include a light emitting material such as an organic material or a quantum dot. The functional layer EL including the light emitting layer may be to emit light having at least one of a blue color, a red color, or a green color in a divided pixel. In the entirety of the active region DM-AA (see FIG. 3) according to one or more embodiments, the functional layer EL may provide light having a blue color.

In one or more embodiments, the functional layer EL may further include a hole control layer, an electron control layer, and/or the like, in addition to the light emitting layer. The hole control layer may be arranged between the first electrode AE and the light emitting layer, and the electron control layer may be arranged between the light emitting layer and the second electrode CE.

The light emitting layer of the functional layer EL may be provided by being patterned so as to correspond to the light emitting region PXA. In addition, the hole control layer and the electron control layer of the functional layer EL may be provided, in common, in a plurality of light emitting regions. For example, in one or more embodiments, each of the hole control layer, the electron control layer, and/or the like, may be provided as a common layer in the entirety of the first to third light emitting regions PXA-B, PXA-G and PXA-R. However, embodiments of the present disclosure are not limited thereto, for example, in one or more embodiments, the hole control layer and the electron control layer may each be provided by being patterned so as to correspond to the light emitting region PXA, or provided to overlap the pixel defining film PDL to be in a shape in which a portion thereof is disconnected.

In one embodiment, the display element layer DP-OLED according to one or more embodiments may further include a capping layer. The capping layer may be arranged on the second electrode CE. The capping layer may be provided, in common, in the plurality of light emitting regions.

In one or more embodiments, the pixel defining film PDL may be arranged on the fifth insulation layer 50 of the circuit layer DP-CL. An opening portion OH may be defined in the pixel defining film PDL. The opening portion OH may correspond to the first electrode AE, and the pixel defining film PDL may expose a portion of a top surface of the first electrode AE through the opening portion OH.

The pixel defining film PDL may have a single-layer structure or a multilayer structure. The pixel defining film PDL may be made of a polymer resin. For example, in one or more embodiments, the pixel defining film PDL may include a polyacrylate-based resin or a polyimide-based resin. In addition, the pixel defining film PDL may further include an inorganic matter in addition to the polymer resin. In one or more embodiments, the pixel defining film PDL may include a light absorbing material, or may include a black pigment or a black dye. The pixel defining film PDL including the black pigment or the black dye may be a black pixel defining film. In one or more embodiments, when the pixel defining film PDL is formed, a carbon black and/or the like, may be used as the black pigment or the black dye. However, embodiments of the present disclosure are not limited thereto.

In one or more embodiments, the pixel defining film PDL may be made of an inorganic matter. For example, the pixel defining film PDL may be made of an inorganic matter such as a silicon nitride (SiNₓ), a silicon oxide (SiOₓ), or a silicon oxynitride (SiOₓN_{y}).

Referring to FIG. 5C, the display element layer DP-OLEDa according to one or more embodiments may include the light emitting element ED-a, a sacrificial pattern SP, a pixel defining film PDL-a, and a partition wall PW. Compared to the display element layer DP-OLED illustrated in FIGS. 5A and 5B, the display element layer DP-OLEDa illustrated in FIG. 5C is different in that the sacrificial pattern SP and the partition wall PW are further included, and in terms of the structure of the light emitting element ED-a. The light emitting element ED-a illustrated in FIG. 5C may include a first electrode AE, a light emitting pattern EP, and a second electrode CE.

The first electrode AE may be arranged on a fifth insulation layer 50 of a circuit layer DP-CL. The same as the content of the first electrode AE described with reference to FIGS. 5A and 5B may apply to the first electrode AE in the light emitting element ED-a illustrated in FIG. 5C.

The sacrificial pattern SP may be arranged between the first electrode AE and the pixel defining film PDL-a. A sacrificial opening portion OP-S that exposes a portion of a top surface of the first electrode AE may be defined in the sacrificial pattern SP. The sacrificial opening portion OP-S may overlap a light emitting opening portion OP-E to be described in more detail later on a plane.

The pixel defining film PDL-a may be arranged on the fifth insulation layer 50 of the circuit layer DP-CL. The light emitting opening portion OP-E may be defined in the pixel defining film PDL-a. On a plane, the light emitting opening portion OP-E may overlap the first electrode AE, and the pixel defining film PDL-a may expose at least a portion of the first electrode AE through the light emitting opening portion OP-E.

In addition, the light emitting opening portion OP-E may correspond to the sacrificial opening portion OP-S of the sacrificial pattern SP. According to one or more embodiments, the top surface of the first electrode AE may be spaced and/or apart (e.g., spaced apart or separated) from the pixel defining film PDL-a with the sacrificial pattern SP therebetween on a cross-section, and accordingly, the first electrode AE may be protected against damage in a process of forming the light emitting opening portion OP-E.

A surface area of the light emitting opening portion OP-E may be less than a surface area of the sacrificial opening portion OP-S on a plane. For example, in one or more embodiments, an inner side surface of the pixel defining film PDL-a, which defines the light emitting opening portion OP-E, may be more adjacent to a center of the first electrode AE than an inner side surface of the sacrificial pattern SP, which defines the sacrificial opening portion OP-S. However, embodiments of the present disclosure are not limited thereto, for example, in one or more embodiments, the inner side surface of the sacrificial pattern SP, which defines the sacrificial opening portion OP-S, may be substantially aligned with the inner side surface of the pixel defining film PDL-a, which defines the light emitting opening portion OP-E. Here, the light emitting region PXA may be considered to be a region of the first electrode AE that is exposed from the sacrificial opening portion OP-S corresponding thereto.

The pixel defining film PDL-a may include an inorganic insulation material. For example, in one or more embodiments, the pixel defining film PDL may include a silicon nitride (SiNₓ). The pixel defining film PDL may be arranged between the first electrode AE and the partition wall PW to block an electrical connection between the first electrode AE and the partition wall PW.

The light emitting pattern EP may be arranged on the first electrode AE. The light emitting pattern EP may include a light emitting layer including a light emitting material. The light emitting pattern EP may further include a hole control layer arranged between the first electrode AE and the light emitting layer. The hole control layer may include a hole injection layer and a hole transport layer. In addition, the light emitting pattern EP may further include an electron control layer arranged on the light emitting layer. The electron control layer may include an electron transport layer and an electron injection layer.

The light emitting pattern EP may be patterned by a tip part defined in the partition wall PW. The light emitting pattern EP may be arranged inside the sacrificial opening portion OP-S, the light emitting opening portion OP-E, and a partition wall opening portion OP-P. The light emitting pattern EP may cover a portion of a top surface of the pixel defining film PDL-a, which is exposed from the partition wall opening portion OP-P.

The second electrode CE may be arranged on the light emitting pattern EP. The second electrode CE may be patterned by the tip part defined in the partition wall PW. At least a portion of the second electrode CE may be arranged in the partition wall opening portion OP-P. The second electrode CE may be in contact with a first inner side surface S-L1 of a first partition wall layer L1. The second electrode CE may have conductivity (e.g., electrical conductivity). The second electrode CE may be made of one or more suitable materials such as a metal, a transparent conductive oxide (TCO), or a conductive polymeric material, as long as the second electrode CE is capable of having conductivity. For example, in one or more embodiments, the second electrode CE may include silver (Ag), magnesium (Mg), lead (Pb), copper (Cu), or a compound thereof.

The display element layer DP-OLEDa according to one or more embodiments may further include a capping pattern. The capping pattern may be arranged in the partition wall opening portion OP-P, and be arranged on the second electrode CE. The capping pattern may be patterned by the tip part defined in the partition wall PW.

The partition wall PW may be arranged on the pixel defining film PDL-a. The partition wall opening portion OP-P may be defined in the partition wall PW. The partition wall opening portion OP-P may correspond to the light emitting opening portion OP-E, and may expose at least a portion of the first electrode AE.

The partition wall PW may have an undercut shape on a cross-section. The partition wall PW may include a plurality of layers stacked in sequence, and at least one of the plurality of layers may be recessed from the other layers. Accordingly, the partition wall PW may include the tip part.

The partition wall PW may include the first partition wall layer L1 and a second partition wall layer L2. The first partition wall layer L1 may be arranged on the pixel defining film PDL-a, and the second partition wall layer L2 may be arranged on the first partition wall layer L1. As illustrated in FIG. 5C, in one or more embodiments, a thickness of the first partition wall layer L1 may be greater than a thickness of the second partition wall layer L2, but embodiments of the present disclosure are not limited thereto.

In one or more embodiments, the first partition wall layer L1 may be relatively recessed from the second partition wall layer L2 with respect to the light emitting region PXA. The first partition wall layer L1 may be undercut relative to the second partition wall layer L2. A portion, which protrudes from the first partition wall layer L1 toward the light emitting region PXA, of the second partition wall layer L2 may be defined as the tip part in the partition wall PW.

The partition wall opening portion OP-P defined in the partition wall PW may include a first region A1 and a second region A2. The first partition wall layer L1 may include the first inner side surface S-L1 that defines the first region A1 of the partition wall opening portion OP-P, and the second partition wall layer L2 may include a second inner side surface S-L2 that defines the second region A2. The second inner side surface S-L2 of the second partition wall layer L2 may be more adjacent to the center of the first electrode AE than the first inner side surface S-L1 of the first partition wall layer L1 on a cross-section. The first inner side surface S-L1 may be recessed from the second inner side surface S-L2 in a direction that is away from the center of the first electrode AE. Accordingly, the second partition wall layer L2 protruding toward the light emitting region PXA may include the tip part.

The first region A1 may have a width that is different from a width of the second region A2. In one or more embodiments, the width of the first region A1 may be greater than the width of the second region A2. In these embodiments, the second region A2 of the partition wall opening portion OP-P may be a region that defines the tip part.

Each of the first partition wall layer L1 and the second partition wall layer L2 may include a conductive material (e.g., electron conductor). For example, the conductive material may include a metal, a transparent conductive oxide (TCO), and/or a (e.g., any suitable) combination thereof. For example, the metal may include gold (Au), silver (Ag), aluminum (Al), magnesium (Mg), lithium (Li), molybdenum (Mo), titanium (Ti), copper (Cu), or an alloy. The transparent conductive oxide may include an indium tin oxide (ITO), an indium zinc oxide (IZO), a zinc oxide, an indium oxide, an indium gallium oxide, an indium gallium zinc oxide (IGZO), or an aluminum zinc oxide.

FIG. 5C illustrates an embodiment in which each of the first inner side surface S-L1 and the second inner side surface S-L2 is normal (e.g., perpendicular) to the top surface of the pixel defining film PDL-a. However, embodiments of the present disclosure are not limited thereto. For example, in one or more embodiments, the partition wall PW may have a tapered shape, or may have a reverse tapered shape.

The partition wall PW may receive a driving voltage. Accordingly, the second electrode CE may be electrically connected to the partition wall PW to receive the driving voltage. For example, in one or more embodiments, the second electrode CE may be electrically connected to the first partition wall layer L1 of the partition wall PW.

A dummy pattern DMA may be defined on the partition wall PW. The dummy pattern DMA may be defined between the partition wall PW and an inorganic encapsulation pattern IOP on a cross-section. The dummy pattern DMA may be a portion which remains after removing at least a portion of each of dummy layers formed on a top surface of the partition wall PW during a process of manufacturing a display device to be described in more detail later.

Referring to FIGS. 5A to 5C again, the encapsulation layer TFE may be arranged on the display element layer DP-OLED, and the encapsulation layer TFE-a may be arranged on the display element layer DP-OLEDa. The encapsulation layer TFE may be arranged on the second electrode CE of the light emitting element ED, and the encapsulation layer TFE-a may be arranged on the second electrode CE of the light emitting element ED-a. The encapsulation layer TFE may cover the light emitting element ED, and the encapsulation layer TFE-a may cover the light emitting element ED-a.

Referring to FIGS. 5A and 5B, the encapsulation layer TFE according to one or more embodiments may include an inorganic encapsulation film IOL and a barrier layer PSL. In one or more embodiments, the encapsulation layer TFE may further include an organic encapsulation film OL made of an organic matter.

In one or more embodiments, the inorganic encapsulation film IOL of the encapsulation layer TFE may be arranged on the second electrode CE. The inorganic encapsulation film IOL may protect components of the display panel DP against moisture, oxygen, and/or the like, outside the display panel DP. The inorganic encapsulation film IOL may have a stepped portion according to a structure of the display panel DP arranged therebelow. The inorganic encapsulation film IOL may be provided and arranged along a stepped portion of the opening portion OH defined in the pixel defining film PDL. The inorganic encapsulation film IOL may be arranged along the stepped portion of the display panel DP arranged therebelow, and be provided to have a substantially uniform thickness. The inorganic encapsulation film IOL may be referred to as an “inorganic encapsulation layer.”

In one or more embodiments, the inorganic encapsulation film IOL may be formed through chemical vapor deposition (CVD). The inorganic encapsulation film IOL may include a silicon nitride layer, a silicon oxynitride layer, a silicon oxide layer, a titanium oxide layer, an aluminum oxide layer, and/or the like.

The encapsulation layer TFE may include the barrier layer PSL arranged on the inorganic encapsulation film IOL. The barrier layer PSL may be arranged directly on the inorganic encapsulation film IOL. A bottom surface of the barrier layer PSL may have a stepped portion on the inorganic encapsulation film IOL and along the opening portion OH defined in the pixel defining film PDL. A top surface of the barrier layer PSL may provide a flat surface with a component arranged on the encapsulation layer TFE. The barrier layer PSL may be provided directly on the inorganic encapsulation film IOL to exhibit superior adhesion to the inorganic encapsulation film IOL. The barrier layer PSL may include an inorganic polysilazane compound. The barrier layer PSL may be formed by providing a silazane-based compound directly onto the inorganic encapsulation film IOL and then performing polymerization and curing processes, so that the barrier layer PSL has a sufficient thickness to cover the inorganic encapsulation film IOL provided by following the stepped portion therebelow. In one or more embodiments, the encapsulation layer TFE includes a barrier layer PSL placed directly on the inorganic encapsulation film IOL. The bottom surface of the PSL has a stepped portion that aligns with the opening in the pixel defining film PDL, while the top surface is flat to support other components. The barrier layer PSL, made from an inorganic polysilazane compound, adheres well to the inorganic encapsulation film IOL. It is created by applying a silazane-based compound to the inorganic encapsulation film IOL and then polymerizing and curing it to achieve the necessary thickness to cover the inorganic encapsulation film IOL and follow the stepped portion.

In one or more embodiments, the barrier layer PSL may have a thickness of about 1,000 Å to about 10,000 Å. The barrier layer PSL may be provided to have a thickness of about 1,000 Å or more to effectively protect components of the display panel DP. In addition, according to a method for manufacturing a display device to be described in more detail later, the barrier layer PSL may be formed through inkjet printing and laser curing, and in this regard, the barrier layer PSL having a thickness of at most about 10,000 Å may be formed. In other words, the barrier layer PSL in a display device may have a thickness from about 1,000 Å to about 10,000 Å. This thickness is designed to effectively protect the display panel components. The barrier layer may be formed using inkjet printing and laser curing methods, ensuring it does not exceed 10,000 Å in thickness.

The barrier layer PSL provided to have sufficient thickness may sufficiently or adequately cover components of the light emitting element ED arranged in the opening portion OH. Accordingly, the components of the light emitting element ED arranged in the opening portion OH may be sufficiently covered to protect the functional layer EL.

The barrier layer PSL may include an inorganic polysilazane compound. The barrier layer PSL may include an inorganic polymer layer including Si and N, or an inorganic polymer layer including Si, N, and O. For example, in one or more embodiments, the barrier layer PSL may include a silicon nitride, or include a silicon oxynitride.

The barrier layer PSL may be formed from a compound having a repeating unit represented by Formula 1.

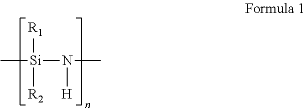

In Formula 1, R₁ and R₂ may each independently be hydrogen, an alkyl group of 1 to 10 carbon atoms, or an aryl group of 6 to 30 ring-forming carbon atoms, and n may be an integer of 2 or more.

In one or more embodiments, Formula 1 may be represented by Formula 1-1 or Formula 1-2. For example, in one or more embodiments, the barrier layer PSL may be formed from a compound having a repeating unit represented by Formula 1-1. In one or more embodiments, the barrier layer PSL may be formed from a compound having a repeating unit represented by Formula 1-2.

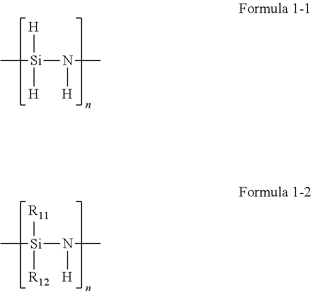

In Formulas 1-1 and 1-2, n may be the same as defined in Formula 1. In Formula 1-2, R₁₁ and R₁₂ may each independently be an alkyl group of 1 to 10 carbon atoms or an aryl group of 6 to 30 ring-forming carbon atoms.

For example, the silazane-based compound having the repeating unit of Formula 1 may have a structure of Formula 2. However, this is a mere example, and embodiments of the present disclosure are not limited thereto.

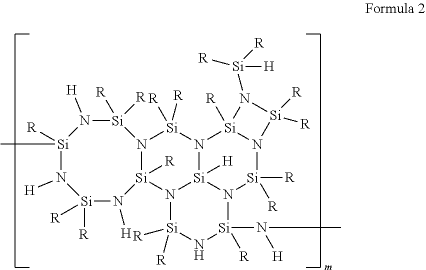

In Formula 2, R may be hydrogen, an alkyl group of 1 to 10 carbon atoms, or an aryl group of 6 to 30 ring-forming carbon atoms, and m may be an integer of 2 or more. For example, in one or more embodiments, in Formula 2, all of a plurality of R moieties may each be hydrogen. In one or more embodiments, in Formula 2, the plurality of R moieties may be each an alkyl group of 1 to 10 carbon atoms or an aryl group of 6 to 30 ring-forming carbon atoms.

The silazane-based compound represented by Formula 2 may be termed perhydropolysilazane (PHPS). For example, in one or more embodiments, the barrier layer PSL may include inorganic polysilazane formed from PHPS.

In an air state having a specified silazane-based composition, the repeating unit of Formula 1 may be combined arbitrarily or at random to form an inorganic polymer layer including Si and N, or an inorganic polymer layer including Si, N, and O. Accordingly, the barrier layer PSL may include the inorganic polymer layer including Si and N, or the inorganic polymer layer including Si, N, and O.

The barrier layer PSL including the inorganic polysilazane compound may replace a stacking structure of an organic encapsulation film and an upper inorganic encapsulation film of components of a typical encapsulation layer. For example, a single barrier layer PSL including the silazane-based compound may replace the stacking structure of the organic encapsulation film and the upper inorganic encapsulation film so that when the display panel is manufactured, a process of forming the encapsulation layer TFE is simplified, and a thickness of the encapsulation layer TFE is reduced. In addition, in order to secure reliability, a typical display device additionally requires a process of removing an organic encapsulation film after the organic encapsulation film is formed in a partial region for bonding between a lower inorganic encapsulation film and the upper inorganic encapsulation film. However, in the display device according to one or more embodiments of the present disclosure, the barrier layer PSL including the inorganic polysilazane compound may be arranged directly on the inorganic encapsulation film IOL so that bonding between inorganic layers is performed without additional process. Accordingly, the display device according to one or more embodiments of the present disclosure may have improved process economic feasibility and exhibit superior reliability.

The barrier layer PSL may have a refractive index of about 1.53 to about 1.90. In one or more embodiments, the barrier layer PSL may include the silazane-based compound to have relatively high density compared to an organic film. Accordingly, the barrier layer PSL including the silazane-based compound may exhibit a relatively high refractive index value compared to the organic film.

Referring to FIG. 5B, in one or more embodiments, the encapsulation layer TFE may further include an organic encapsulation film OL. Compared to the encapsulation layer TFE according to one or more embodiments illustrated in FIG. 5A, the encapsulation layer TFE illustrated in FIG. 5B may be a layer in which the organic encapsulation film OL is arranged between the inorganic encapsulation film IOL and the barrier layer PSL. In the encapsulation layer TFE illustrated in FIG. 5B, the barrier layer PSL including the inorganic polysilazane compound may replace the upper inorganic encapsulation film of the components of the typical encapsulation layer.

For example, in one or more embodiments, the encapsulation layer TFE may include the inorganic encapsulation film IOL, the organic encapsulation film OL, and the barrier layer PSL that are stacked in sequence on the display element layer DP-OLED. The organic encapsulation film OL may protect the display element layer DP-OLED against a foreign matter such as dust particles.

The organic encapsulation film OL may be formed on the inorganic encapsulation film IOL through inkjet printing and laser curing. When the display panel DP is manufactured, the organic encapsulation film OL and the barrier layer PSL may be formed in sequence through the same process method using inkjet printing and laser curing so that the process of forming the encapsulation layer TFE is simplified.

Referring to FIG. 5C, the encapsulation layer TFE-a according to one or more embodiments may be arranged on the display element layer DP-OLEDa. The encapsulation layer TFE-a may include the inorganic encapsulation pattern IOP and a barrier layer PSL-a. Compared to the encapsulation layer TFE illustrated in FIGS. 5A and 5B, the encapsulation layer TFE-a illustrated in FIG. 5C is different in that the inorganic encapsulation pattern IOP is included instead of the inorganic encapsulation film IOL, and in terms of an arrangement shape of the barrier layer PSL-a. The inorganic encapsulation pattern IOP illustrated in FIG. 5C may be a component corresponding to the inorganic encapsulation film IOL of the encapsulation layer TFE illustrated in FIGS. 5A and 5B. The inorganic encapsulation pattern IOP may be referred to as an “inorganic encapsulation layer.” For example, the “inorganic encapsulation layer” used herein refers to the inorganic encapsulation pattern IOP or the inorganic encapsulation film IOL.

The inorganic encapsulation pattern IOP may correspond to the light emitting opening portion OP-E. The inorganic encapsulation pattern IOP may be arranged on the second electrode CE. A portion of the inorganic encapsulation pattern IOP may be provided in the partition wall opening portion OP-P, and another portion of the inorganic encapsulation pattern IOP may be provided on the partition wall PW. For example, in one or more embodiments, the inorganic encapsulation pattern IOP may be arranged to cover a top surface of the second electrode CE, one side surface of the partition wall PW, and at least a portion of a side surface or a top surface of the dummy pattern DMA. The inorganic encapsulation pattern IOP may be arranged along a stepped portion of the display panel DP-a arranged therebelow, and be provided to have a substantially uniform thickness. FIG. 5C illustrates the inorganic encapsulation pattern IOP having a substantially uniform thickness, but unlike that illustrated, in one or more embodiments, the inorganic encapsulation pattern IOP may have a non-uniform thickness due to an undercut portion of the partition wall PW.

The barrier layer PSL-a may be arranged on the inorganic encapsulation pattern IOP. The barrier layer PSL-a may be arranged directly on the inorganic encapsulation pattern IOP to provide a flat top surface while covering the inorganic encapsulation pattern IOP. In addition, a portion of the barrier layer PSL-a may cover the top surface, on which the dummy pattern DMA is not arranged, of the partition wall PW. In the display device according to one or more embodiments, inorganic layer bonding of the barrier layer PSL-a to the inorganic encapsulation pattern IOP is achieved to increase a film density of the barrier layer PSL-a so that permeation of moisture/oxygen or chemical materials is suppressed or reduced. The same as the content regarding the barrier layer PSL described with reference to FIGS. 5A and 5B may apply to the barrier layer PSL-a described with reference to FIG. 5C except the shape arranged on the inorganic encapsulation pattern IOP.

In one or more embodiments, the encapsulation layer TFE-a in FIG. 5C may further include an organic encapsulation film made of an organic matter. When the encapsulation layer TFE-a illustrated in FIG. 5C further includes the organic encapsulation film, the organic encapsulation film may be arranged between the inorganic encapsulation pattern IOP and the barrier layer PSL-a. For example, in one or more embodiments, the encapsulation layer TFE-a may include the inorganic encapsulation pattern IOP, the organic encapsulation film, and the barrier layer PSL-a that are stacked in sequence. The organic encapsulation film may cover the inorganic encapsulation pattern IOP arranged below/underneath the organic encapsulation film, and provide a flat top surface that substantially does not have a stepped portion. The barrier layer PSL-a may be arranged directly on a flat top surface provided by the organic encapsulation film.

Referring to FIGS. 5A to 5C again, the input sensor INS may be arranged on the display panel DP or DP-a. The input sensor INS may be arranged directly on the barrier layer PSL or PSL-a. The input sensor INS may include a sensor base layer 210, a first sensor conductive layer 220, a sensor insulation layer 230, a second sensor conductive layer 240, and a sensor cover layer 250.

The sensor base layer 210 may be arranged directly on the display panel DP or DP-a. In one or more embodiments, the sensor base layer 210 may be an inorganic layer including at least one of a silicon nitride, a silicon oxynitride, or a silicon oxide. In one or more embodiments, the sensor base layer 210 may be an organic layer including an epoxy-based resin, an acrylic-based resin, or an imide-based resin. The sensor base layer 210 may have a single-layer structure, or have a multilayer structure in which layers are stacked in the third direction DR3.

Each of the first sensor conductive layer 220 and the second sensor conductive layer 240 may have a single-layer structure, or have a multilayer structure in which layers are stacked in the third direction DR3.

The conductive layer having a single-layer structure may include a metal layer or a transparent conductive layer. The metal layer may include molybdenum, silver, titanium, copper, aluminum, or an alloy thereof. The transparent conductive layer may include a transparent conductive oxide such as an indium tin oxide, an indium zinc oxide, a zinc oxide, or an indium zinc tin oxide. In one or more embodiments, the transparent conductive layer may include a conductive polymer such as poly(3,4-ethylenedioxythiophene) (PEDOT), a metal nanowire, graphene, and/or the like.

The conductive layer having a multilayer structure may include metal layers. The metal layers may have, for example, a three-layer structure of titanium/aluminum/titanium. In one or more embodiments, the conductive layer having a multilayer structure may include at least one metal layer and at least one transparent conductive layer.

The sensor insulation layer 230 may be arranged between the first sensor conductive layer 220 and the second sensor conductive layer 240. The sensor cover layer 250 may be arranged on the sensor insulation layer 230, and cover the second sensor conductive layer 240. The second sensor conductive layer 240 may include a conductive pattern. The sensor cover layer 250 may cover the conductive pattern, and reduce or eliminate a probability of damage to the conductive pattern in a subsequent process.

In one or more embodiments, each of the sensor insulation layer 230 and the sensor cover layer 250 may include an inorganic film. The inorganic film may include at least one of an aluminum oxide, a titanium oxide, a silicon oxide, a silicon nitride, a silicon oxynitride, a zirconium oxide, or a hafnium oxide.

In one or more embodiments, each of the sensor insulation layer 230 and the sensor cover layer 250 may include an organic film. The organic film may include at least one of acryl-based resin, a methacryl-based resin, polyisoprene, a vinyl-based resin, an epoxy-based resin, a urethane-based resin, a cellulose-based resin, a siloxane-based resin, a polyimide-based resin, a polyamide-based resin, or a perylene-based resin.

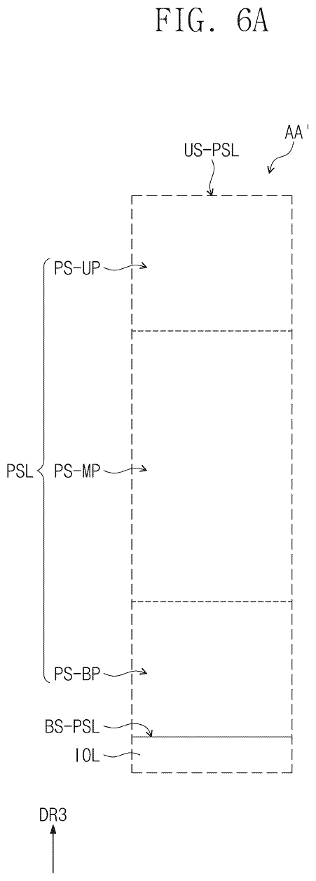

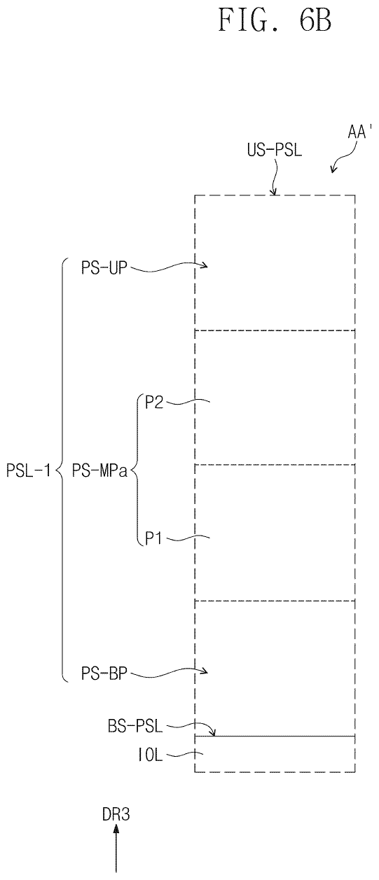

FIGS. 6A and 6B are each a view illustrating a barrier layer according to one or more embodiments of the present disclosure. FIGS. 6A and 6B may each illustrate a portion corresponding to region AA′ in FIG. 5A. FIG. 6A is a cross-sectional view illustrating a portion of a barrier layer PSL according to one or more embodiments, and FIG. 6B is a cross-sectional view illustrating one or more embodiments of the barrier layer PSL illustrated in FIG. 6A.

Referring to FIG. 6A, the barrier layer PSL according to one or more embodiments may include portions different in refractive index. A refractive index of a first portion PS-BP adjacent to an inorganic encapsulation film IOL may be less than a refractive index of a second portion PS-UP spaced and/or apart (e.g., spaced apart or separated) from the inorganic encapsulation film IOL.

In one or more embodiments, the refractive index of the barrier layer PSL may gradually increase in a direction that is away from the inorganic encapsulation film IOL. The refractive index of the barrier layer PSL may gradually increase in the direction that is away from the inorganic encapsulation film IOL, or may gradually change such that refractive index values are similar inside a specified thickness range, and refractive index values outside the specified thickness range are distinguished from the refractive index values inside the specified thickness range (e.g., change in a step-wise manner). That is, in the context of the present disclosure, a gradual increase refers to that the refractive index transitions steadily over a certain distance rather than changing abruptly. This can happen in two ways: either the refractive index changes smoothly and continuously as it moves away from the inorganic encapsulation film IOL, or it changes in a step-wise manner, where the refractive index values remain similar within a specified thickness range but differ outside this range.

In one or more embodiments illustrated in FIG. 6A, the first portion PS-BP including a bottom surface BS-PSL, which is adjacent to the inorganic encapsulation film IOL, of the barrier layer PSL may have a first refractive index value. The second portion PS-UP including a top surface US-PSL may have a second refractive index value greater than the first refractive index value. A third portion PS-MP arranged between the first portion PS-BP and the second portion PS-UP may have a third refractive index value that is a value between the first refractive index and the second refractive index.

In one or more embodiments, at least some of the first portion PS-BP, the second portion PS-UP, or the third portion PS-MP may not be provided. For example, at least some of the first portion PS-BP, the second portion PS-UP, or the third portion PS-MP may not be provided according to the irradiance of laser light provided during forming the barrier layer PSL, in the total thickness of the barrier layer PSL, and/or the like. In the barrier layer PSL illustrated in FIG. 6A, the first portion PS-BP may have a thickness of about 0 Å to about 8000 Å. The second portion PS-UP may have a thickness of about 0 Å to about 1000 Å, and the third portion PS-MP may have a thickness of about 0 Å to about 4000 Å. However, embodiments of the present disclosure are not limited thereto.

In addition, referring to FIG. 6B, a barrier layer PSL-1 according to one or more embodiments may include four portions having refractive index values distinguished from each other. Compared to the barrier layer PSL according to one or more embodiments illustrated in FIG. 6A, the barrier layer PSL-1 illustrated in FIG. 6B may include a third portion PS-MPa including two sub-portions P1 and P2 having different refractive index values from each other. In the third portion PS-MPa, a refractive index of a second sub-portion P2 may be greater than a refractive index of a first sub-portion P1.

For example, in one or more embodiments, in the barrier layer PSL-1 illustrated in FIG. 6B, a first portion PS-BP may have a thickness of about 0 Å to about 8000 Å. A second portion PS-UP may have a thickness of about 0 Å to about 1000 Å. In the third portion PS-MPa, the first sub-portion P1 may have a thickness of about 1000 Å to about 3000 Å, and the second sub-portion P2 may have a thickness of about 0 Å to about 1000 Å. However, embodiments of the present disclosure are not limited thereto.

In one or more embodiments illustrated in FIG. 6A, if (e.g., when) the barrier layer PSL is a layer including a silicon nitride, the refractive index of the first portion PS-BP may be about 1.53 to about 1.55, the refractive index of the third portion PS-MP may be about 1.54 to about 1.80, and the refractive index of the second portion PS-UP may be about 1.80 or more. In addition, in one or more embodiments illustrated in FIG. 6A, if (e.g., when) the barrier layer PSL is a layer including a silicon oxynitride, the refractive index of the first portion PS-BP may be about 1.53 to about 1.55, the refractive index of the third portion PS-MP may be about 1.54 to about 1.68, and the refractive index of the second portion PS-UP may be about 1.68 or more.

In one or more embodiments illustrated in FIG. 6B, if (e.g., when) the barrier layer PSL-1 is a layer including a silicon nitride, the refractive index of the first portion PS-BP may be about 1.53 to about 1.55, the refractive index of the first sub-portion P1 of the third portion PS-MPa may be about 1.54 to 1.70, the refractive index of the second sub-portion P2 of the third portion PS-MPa may be about 1.70 to about 1.80, and the refractive index of the second portion PS-UP may be about 1.80 or more. In one or more embodiments illustrated in FIG. 6B, if (e.g., when) the barrier layer PSL-1 is a layer including a silicon oxynitride, the refractive index of the first portion PS-BP may be about 1.53 to about 1.55, the refractive index of the first sub-portion P1 of the third portion PS-MPa may be about 1.54 to 1.60, the refractive index of the second sub-portion P2 of the third portion PS-MPa may be about 1.60 to about 1.68, and the refractive index of the second portion PS-UP may be about 1.68 or more.

In FIGS. 6A and 6B, the respective thicknesses of the portions having refractive index values distinguished from each other are similar to each other, but embodiments of the present disclosure are not limited thereto. The thickness of each of the first portion PS-BP and the second portion PS-UP may be relatively small, and the thickness of the third portion PS-MP or PS-MPa may be larger than other portions. However, the respective thicknesses of the portions are not limited thereto.

In the barrier layer PSL or PSL-1 according to one or more embodiments, the first portion PS-BP may be a silazane-based compound layer including a silazane-based repeating unit of Formula 1 described above. For example, the first portion PS-BP may be a layer including silazane-based repeating units having a low polymerization degree. The first portion PS-BP may be a layer including the silazane-based repeating units without forming a silicon nitride or a silicon oxynitride.

When the thickness of the entire barrier layer PSL or PSL-1 is about 3000 Å or less, a layer including silazane-based units and having a refractive index of about 1.55 or less may not be provided. For example, in one or more embodiments, if (e.g., when) the thickness of the entire barrier layer PSL or PSL-1 is about 3000 Å or less, the first portion PS-BP that is a silazane-based compound layer may not be provided. Accordingly, the barrier layer PSL or PSL-1 may be a layer that includes a plurality of portions including a silicon nitride and having refractive indexes that increase in a thickness direction thereof, or the barrier layer PSL or PSL-1 may be a layer that includes a plurality of portions including a silicon oxynitride and having refractive indexes that increase in the thickness direction. In addition, if (e.g., when) the thickness of the entire barrier layer PSL or PSL-1 is about 3000 Å or less, the barrier layer PSL or PSL-1 may be one silicon nitride layer including a single component and having a similar refractive index range, or may be one silicon oxynitride layer including a single component and having a similar refractive index range.

In the barrier layer PSL or PSL-1 according to one or more embodiments, the second portion PS-UP may be a layer including only a silicon nitride, or a layer including only a silicon oxynitride. In one or more embodiments, the second portion PS-UP having a refractive index of about 1.80 or more and including a silicon nitride may not be provided, or in one or more embodiments, the second portion PS-UP having a refractive index of about 1.68 or more and including a silicon oxynitride may not be provided.

In one or more embodiments, the barrier layer PSL or PSL-1 may be provided only with one portion PS-MP having similar refractive index values. In one or more embodiments, in the barrier layer PSL or PSL-1, a refractive index of the top surface US-PSL may be greater than a refractive index of the bottom surface BS-PSL.

The same as the content regarding the barrier layer PSL or PSL-1 described with reference to FIGS. 6A and 6B may apply to the barrier layer PSL-a included in the encapsulation layer TFE-a in FIG. 5C except the arrangement shape.

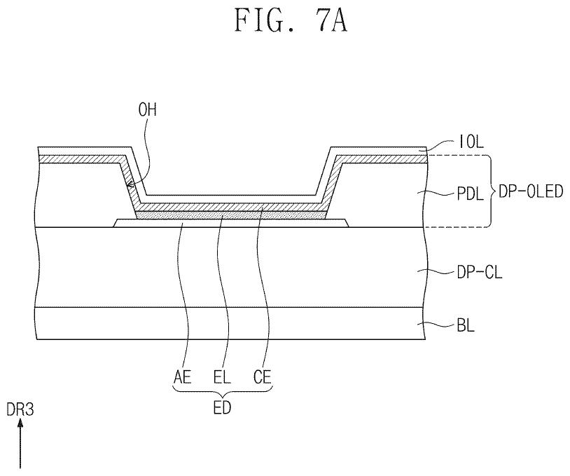

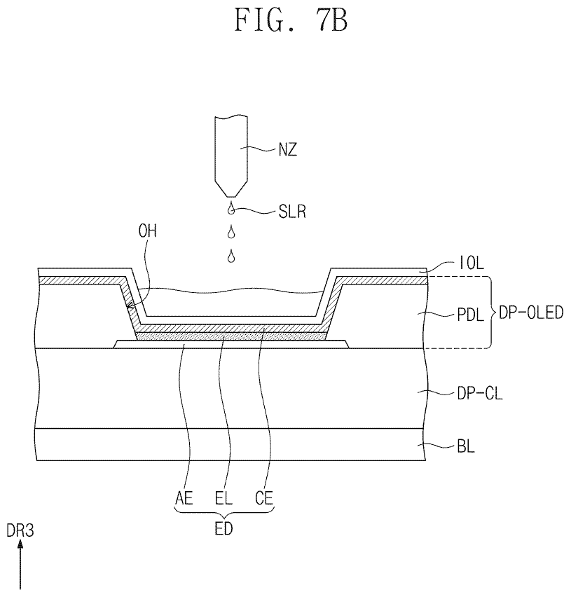

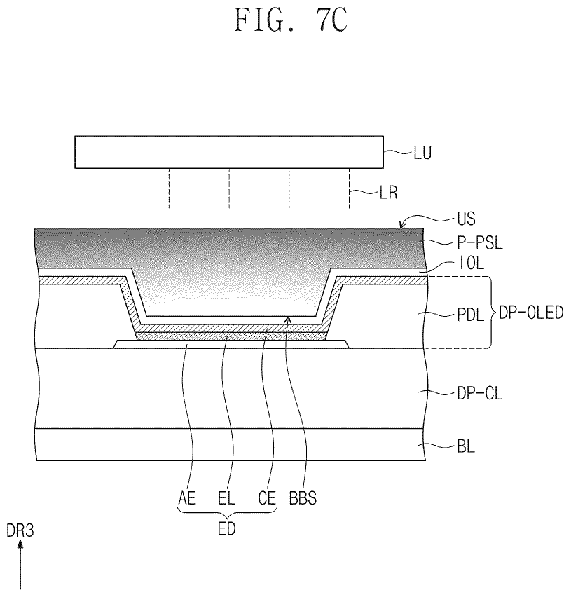

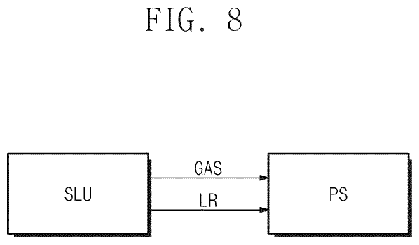

FIGS. 7A to 7C are each a schematic view illustrating one step (e.g., one act or one task) of a method for manufacturing a display device according to one or more embodiments. FIGS. 7A to 7C may be views for explaining a step (e.g., an act or a task) of forming the encapsulation layer TFE illustrated in FIG. 5A of the display device according to one or more embodiments. FIG. 8 is a schematic block diagram illustrating a step (e.g., an act or a task) of forming a barrier layer according to one or more embodiments. Hereinafter, a method for manufacturing a display device according to one or more embodiments will be described with reference to FIGS. 7A to 7C and FIG. 8.

The method for manufacturing the display device according to one or more embodiments may include steps of providing a base layer, forming a circuit layer, forming a display element layer, forming an inorganic encapsulation film, and forming a barrier layer. In addition, the method for manufacturing the display device according to one or more embodiments may further include a step (e.g., an act or a task) of forming an organic encapsulation film. The method for manufacturing the display device according to one or more embodiments will be described by applying the same as the content regarding the components of the display device described with reference to FIGS. 1 to 4, 5A-5C, 6A and 6B.

FIG. 7A illustrates a portion of a display module in which a base layer BL, a circuit layer DP-CL, and a display element layer DP-OLED are arranged in sequence. The circuit layer DP-CL including a conductive pattern and a plurality of insulation layers may be formed on the provided base layer BL.

The step (e.g., act or task) of forming the display element layer DP-OLED may be performed after the step (e.g., act or task) of forming the circuit layer DP-CL is performed. The step (e.g., act or task) of forming, on the circuit layer DP-CL, the display element layer DP-OLED including a light emitting element ED may be performed after the circuit layer DP-CL is formed.

The step (e.g., act or task) of forming an inorganic encapsulation film IOL that covers the light emitting element ED may be performed after the step (e.g., act or task) of forming the display element layer DP-OLED. The inorganic encapsulation film IOL may be formed through chemical vapor deposition (CVD).

The step (e.g., act or task) of forming, on the inorganic encapsulation film IOL, the barrier layer PSL (see FIG. 5A) including an inorganic polysilazane compound may be performed after the inorganic encapsulation film IOL is formed. The barrier layer may be formed to be arranged directly on the inorganic encapsulation film IOL.

FIGS. 7B and 7C illustrate an embodiment of part of the step (e.g., act or task) of forming the barrier layer. The step (e.g., act or task) of forming the barrier layer may include steps of providing a silazane resin composition SLR through inkjet printing to form a preliminary barrier layer P-PSL, and emitting laser light LR onto the preliminary barrier layer P-PSL to form the barrier layer P-PSL.

FIG. 7B illustrates an embodiment in which the silazane resin composition SLR is provided through inkjet printing. The silazane resin composition SLR may be provided directly on the inorganic encapsulation film IOL through a nozzle NZ. The silazane resin composition SLR may fill an opening portion OH, and be provided to have a sufficient thickness to cover the inorganic encapsulation film IOL.

The silazane resin composition SLR may include a silazane compound including the unit represented by Formula 1 described above, and an organic solvent. As the silazane resin composition SLR includes the organic solvent, the silazane resin composition SLR may be easily discharged through the nozzle NZ, and be repeatedly provided using an inkjet printing apparatus so that a viscosity thereof is adjusted to allow the silazane resin composition SLR on the inorganic encapsulation film IOL to have a sufficient thickness. For example, in one or more embodiments, the viscosity of the silazane resin composition SLR may be about 1 cP to about 50 cP, but embodiments of the present disclosure are not limited thereto. The organic solvent is not limited, and any organic solvent may be used as long as being capable of dissolving a silazane compound and being used in the inkjet printing apparatus.

In one or more embodiments, the silazane resin composition SLR may be provided on the organic encapsulation film OL (see FIG. 5B). For example, the organic encapsulation film OL may be formed on the inorganic encapsulation film IOL, and the silazane resin composition SLR may be provided directly on the organic encapsulation film OL. The organic encapsulation film OL may be formed by providing a composition including an organic matter on the inorganic encapsulation film IOL through inkjet printing and then curing the composition by emitting laser light. When the display device according to one or more embodiments is manufactured, the organic encapsulation film OL and the barrier layer PSL (see FIGS. 5A and 5B) may be formed in sequence through the same process method using inkjet printing and laser curing so that the manufacture process is simplified, and equipment costs required for chemical vapor deposition (CVD) used in forming a typical upper inorganic encapsulation layer are reduced.

According to one or more embodiments of the present disclosure, FIG. 7C illustrates the step (e.g., act or task) of emitting the laser light LR onto the preliminary barrier layer P-PSL to form the barrier layer. A laser irradiation equipment LU may be arranged above a top surface US of the preliminary barrier layer P-PSL provided to fill the opening portion OH and cover the inorganic encapsulation film IOL. The laser light LR may be emitted from the laser irradiation equipment LU so that the laser light LR is delivered in a direction from the top surface US of the preliminary barrier layer P-PSL to a bottom surface BSS of the preliminary barrier layer P-PSL.

When the laser light LR is emitted to be delivered in the direction from the top surface US to the bottom surface BSS of the preliminary barrier layer P-PSL, a polymerization degree and a curing degree of the silazane-based compound of the preliminary barrier layer P-PSL may be high in a portion adjacent to the top surface US, and the polymerization degree and the curing degree of the silazane-based compound may gradually decrease toward the bottom surface BSS. FIG. 7C illustrates a grayscale that gradually changes from the top surface US to the bottom surface BSS. For example, in one or more embodiments, when the laser light LR is emitted onto the preliminary barrier layer P-PSL, the polymerization of the silazane-based compound may be performed in the direction from the top surface US to the bottom surface BSS in a different degree. Accordingly, in the finally formed barrier layer PSL (see FIG. 5A), an inorganic film of a silicon nitride or a silicon oxynitride may be formed on the top surface US. If (e.g., when) the laser light LR does not sufficiently reach the bottom surface BSS, the barrier layer may be formed on a portion adjacent to the bottom surface BSS in the form of the silazane-based compound.

For example, if (e.g., when) the finally formed barrier layer PSL (see FIG. 5A) has a thickness of more than about 3000 Å, the preliminary barrier layer P-PSL for forming a barrier layer having a relatively large thickness may not allow the laser light LR to sufficiently reach the bottom surface BSS. Accordingly, the portion adjacent to the bottom surface BSS of the barrier layer PSL may include the silazane-based compound. As the laser light LR sufficiently reaches a portion adjacent to the top surface US of the barrier layer PSL, a silicon nitride or a silicon oxynitride formed from the silazane-based compound may be included.

If (e.g., when) the finally formed barrier layer PSL (see FIG. 5A) has a thickness of about 3000 Å or less, the thickness of the preliminary barrier layer P-PSL may be relatively small so that the laser light LR emitted from the laser irradiation equipment LU is sufficiently transmitted to the bottom surface BSS. Accordingly, the finally formed barrier layer PSL (see FIG. 5A) may not substantially include the silazane-based compound, and may include a silicon nitride or include a silicon oxynitride.

In addition, the portion adjacent to the top surface US irradiated with the sufficient laser light LR may exhibit a higher refractive index value than that of the portion adjacent to the bottom surface BSS that is not sufficiently reached by the laser light LR. In one or more embodiments, the refractive index of the barrier layer PSL (see FIG. 5A) may gradually decrease in the direction from the top surface US to the bottom surface BSS.

In one or more embodiments, the laser light LR provided to the preliminary barrier layer P-PSL may have a wavelength of about 172 nm. The step (e.g., act or task) of emitting the laser light LR onto the preliminary barrier layer P-PSL to form the barrier layer may be performed in an N₂ atmosphere or O₂ atmosphere.

When the step (e.g., act or task) of emitting the laser light LR onto the preliminary barrier layer P-PSL to form the barrier layer is performed in the N₂ atmosphere, the barrier layer PSL (see FIG. 5A) may include a silicon nitride. When the step (e.g., act or task) of emitting the laser light LR onto the preliminary barrier layer P-PSL to form the barrier layer is performed in the O₂ atmosphere, the barrier layer PSL (see FIG. 5A) may include a silicon oxynitride.

FIG. 8 is a schematic block diagram illustrating a step (e.g., an act or a task) of forming a barrier layer according to one or more embodiments. “SLU” in FIG. 8 corresponds to a silazane compound unit. “SLU” may include the repeating unit of Formula 1 described above. For example, in one or more embodiments, “SLU” may be a silazane compound unit having a structure of Formula 2 described above.

When the silazane compound unit SLU is reacted with laser light LR under specific gas conditions, an inorganic polysilazane PS may be formed. As described above, if (e.g., when) the gas GAS is N₂, the inorganic polysilazane PS may become a silicon nitride (SiNₓ), and if (e.g., when) the gas GAS is O₂, the inorganic polysilazane PS may become a silicon oxynitride (SiOₓN_{y}).

The silazane compound units SLU provided in the method for manufacturing the display device according to one or more embodiments may not all be modified into the inorganic polysilazanes PS having the same compound construction and physical characteristics. For example, in one or more embodiments, according to the irradiance of the laser light LR, the barrier layer PSL (see FIG. 5A) may include a first portion including the silazane compound unit SLU that is not polymerized, a second portion including the inorganic polysilazane PS having a high refractive index value, and a third portion including the inorganic polysilazane PS having a refractive index value slightly reduced from the refractive index value of the second portion.

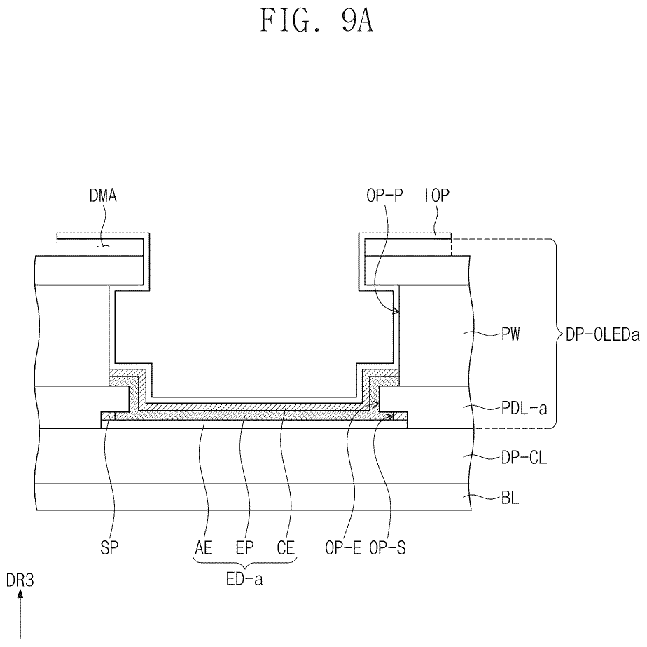

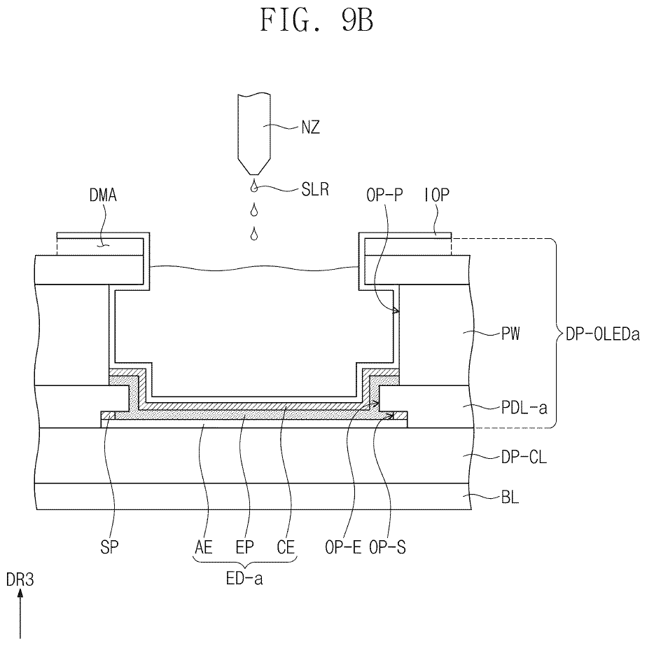

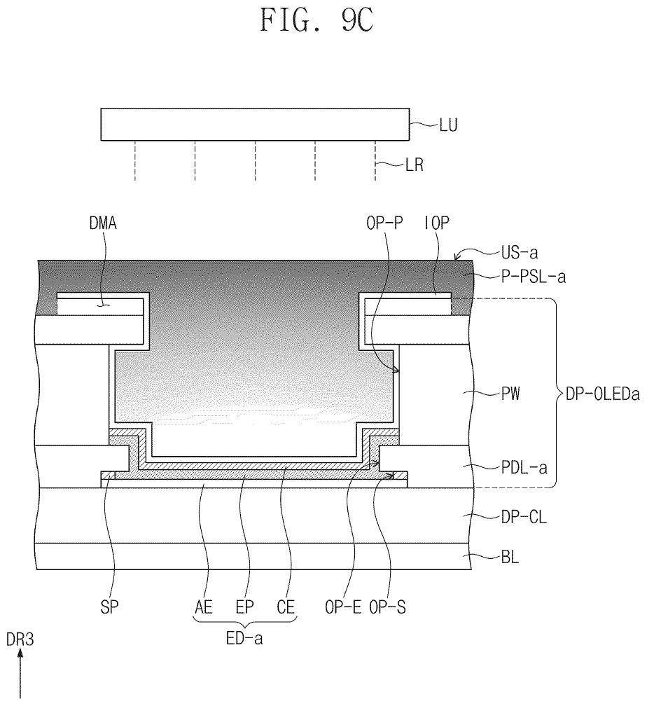

FIGS. 9A to 9C are each a schematic view illustrating one step (e.g., one act or one task) of a method for manufacturing a display device according to one or more embodiments. FIGS. 9A to 9C may be views for explaining a step (e.g., an act or a task) of forming the encapsulation layer TFE-a illustrated in FIG. 5C of the display device according to one or more embodiments. Hereinafter, the method for manufacturing the display device according to one or more embodiments will be described with reference to FIGS. 9A to 9C. The method for manufacturing the display device according to one or more embodiments will be described with reference to FIGS. 9A to 9C by applying the same as the content regarding the components of the display device described with reference to FIGS. 1 to 8, and omitting the redundant content. The same content may apply to the same method as the method for manufacturing the display device described with reference to FIGS. 7A to 8, and the redundant content will not be provided.

The method for manufacturing the display device according to one or more embodiments may include steps of providing a base layer, forming a circuit layer, forming a display element layer, forming an inorganic encapsulation pattern, and forming a barrier layer, and, in some embodiments, may further include a step (e.g., an act or a task) of forming an organic encapsulation film.

FIG. 9A illustrates a portion of a display module in which a base layer BL, a circuit layer DP-CL, and a display element layer DP-OLEDa are arranged in sequence. The circuit layer DP-CL including a conductive pattern and a plurality of insulation layers may be formed on the provided base layer BL.

The step (e.g., act or task) of forming the display element layer DP-OLEDa may be performed after the step (e.g., act or task) of forming the circuit layer DP-CL is performed. The step (e.g., act or task) of forming, on the circuit layer DP-CL, the display element layer DP-OLEDa including a light emitting element ED-a may be performed after the circuit layer DP-CL is formed.

The step (e.g., act or task) of forming an inorganic encapsulation pattern IOP that covers the light emitting element ED-a may be performed after the step (e.g., act or task) of forming the display element layer DP-OLEDa. For example, in one or more embodiments, the inorganic encapsulation pattern IOP may be patterned and formed from a preliminary inorganic encapsulation layer by depositing the preliminary inorganic encapsulation layer on the light emitting element ED-a and a partition wall PW, and then etching the preliminary inorganic encapsulation layer through a photoresist process. The inorganic encapsulation pattern IOP may be patterned to overlap the light emitting element ED-a on a plane. The preliminary inorganic encapsulation layer may be formed through chemical vapor deposition (CVD).

A dummy pattern DMA may be formed after the inorganic encapsulation pattern IOP is formed. The dummy pattern DMA may be a portion remaining after a portion of each of dummy layers formed on a top surface of the partition wall PW is removed. The dummy layers may include a first dummy layer which is formed concurrently (e.g., simultaneously) with a light emitting pattern EP through one process, and a second dummy layer which is formed concurrently (e.g., simultaneously) with a second electrode through one process. However, embodiments of the present disclosure are not limited thereto. For example, in some embodiments, if (e.g., when) the light emitting element ED-a further includes a capping pattern arranged on a second electrode CE, the dummy layers may further include a third dummy layer formed concurrently (e.g., simultaneously) with the capping pattern through one process.

The step (e.g., act or task) of forming, on the inorganic encapsulation pattern IOP, the barrier layer PSL-a (FIG. 5C) including an inorganic polysilazane may be performed after the inorganic encapsulation pattern IOP and the dummy pattern DMA are formed. The barrier layer may be formed to be arranged directly on the inorganic encapsulation pattern IOP.

FIGS. 9B and 9C illustrate an embodiment of part of the step (e.g., act or task) of forming the barrier layer. The step (e.g., act or task) of forming the barrier layer may include steps of providing a silazane resin composition SLR through inkjet printing to form a preliminary barrier layer P-PSL-a, and emitting laser light LR onto the preliminary barrier layer P-PSL-a to form the barrier layer PSL-a.

FIG. 9B illustrates an embodiment in which the silazane resin composition SLR is provided through inkjet printing. The silazane resin composition SLR may be provided directly on the inorganic encapsulation pattern IOP through a nozzle NZ. The silazane resin composition SLR may fill a light emitting opening portion OP-E and a partition wall opening portion OP-P, and be provided to have a sufficient thickness to cover the inorganic encapsulation pattern IOP. The same as the content described with reference to FIGS. 7B and/or the like may apply to the silazane resin composition SLR.

In one or more embodiments, the silazane resin composition SLR may be provided on the organic encapsulation film. For example, the organic encapsulation film may be formed on the inorganic encapsulation pattern IOP, and the silazane resin composition SLR may be provided directly on the organic encapsulation film. The organic encapsulation film may be formed by providing a composition including an organic matter on the inorganic encapsulation pattern IOP through inkjet printing and then curing the composition by emitting laser light. When the display device according to one or more embodiments is manufactured, the organic encapsulation film and the barrier layer PSL-a (see FIG. 5C) may be formed in sequence through the same process method using inkjet printing and laser curing so that the manufacture process is simplified, and equipment costs required for chemical vapor deposition (CVD) used in forming a typical upper inorganic encapsulation layer are reduced. In other words, the silazane resin composition may be applied to an organic encapsulation film that is formed on an inorganic encapsulation pattern. This film is created using inkjet printing and laser curing. By using the same process for both the organic encapsulation film and the barrier layer, the manufacturing process is streamlined, and costs associated with traditional chemical vapor deposition (CVD) methods are lowered.

According to one or more embodiments of the present disclosure, FIG. 9C illustrates the step (e.g., act or task) of emitting the laser light LR onto the preliminary barrier layer P-PSL-a to form the barrier layer. A laser irradiation equipment LU may be arranged above a top surface US-a of the preliminary barrier layer P-PSL-a provided to fill the light emitting opening portion OP-E and the partition wall opening portion OP-P, and cover the inorganic encapsulation pattern IOP. The laser light LR may be emitted from the laser irradiation equipment LU so that the laser light LR is delivered in a direction from the top surface US-a of the preliminary barrier layer P-PSL-a to a bottom surface BSS-a of the preliminary barrier layer P-PSL-a. The same as the content described with reference to FIGS. 7C and/or the like may apply to the step (e.g., act or task) of emitting the laser light LR onto the preliminary barrier layer P-PSL-a to form the barrier layer.

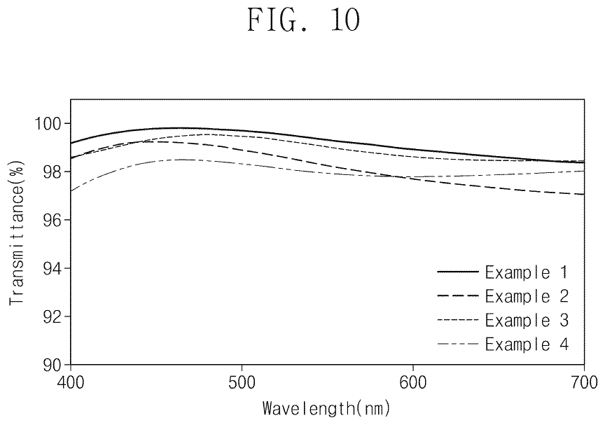

FIG. 10 is a view illustrating a transmittance characteristic of a barrier layer manufactured in a step (e.g., act or task) of a method for manufacturing a display device according to one or more embodiments. FIG. 10 illustrates the transmittance characteristic of the barrier layer according to wavelengths. Examples 1 to 4 are different from each other in process condition for manufacturing the barrier layer. In Example 1, laser light having energy of about 2 J was emitted onto the preliminary barrier layer P-PSL (see FIG. 7C) having a thickness of about 1500 Å. In Example 2, laser light having energy of about 10 J was emitted onto the preliminary barrier layer P-PSL (see FIG. 7C) having a thickness of about 1500 Å. In Example 3, laser light having energy of about 2 J was emitted onto the preliminary barrier layer P-PSL (see FIG. 7C) having a thickness of about 3000 Å. In Example 4, laser light having energy of about 10 J was emitted onto the preliminary barrier layer P-PSL (see FIG. 7C) having a thickness of about 3000 Å.

Referring to the results of Examples 1 to 4, it may be seen that Examples 1 to 4 each exhibits a high transmittance of about 96% or more at a wavelength in a visible light range. For example, when the display device includes the barrier layer including an inorganic polysilazane compound as an encapsulation layer, the display device may exhibit superior reliability characteristics, and also exhibit superior display quality due to the high light transmittance.

The display device according to one or more embodiments may include the barrier layer including the inorganic polysilazane compound and arranged on an inorganic encapsulation layer to exhibit superior reliability characteristics. In the display device according to one or more embodiments, if (e.g., when) the barrier layer including the inorganic polysilazane compound is arranged directly on the inorganic encapsulation layer, inorganic film bonding may be achieved between the barrier layer including the inorganic polysilazane compound and the inorganic encapsulation layer. Accordingly, components of a display panel may be sufficiently protected to exhibit high reliability characteristics. In addition, if (e.g., when) the display device according to one or more embodiments further includes an organic encapsulation film between the inorganic encapsulation layer and the barrier layer, moisture, oxygen, chemical materials, and/or the like may be effectively blocked by the organic encapsulation film and the barrier layer so as to stably protect the components of the display panel.

A method for manufacturing a display device according to one or more embodiments may include a step (e.g., act or task) of forming a barrier layer including an inorganic polysilazane compound directly on an inorganic encapsulation layer to exhibit superior and beneficial process economic feasibility. In the step (e.g., act or task) of forming the barrier layer, a silazane resin composition may be provided through inkjet printing so that the barrier layer has a sufficient thickness, and laser light may be emitted thereon so that the barrier layer has high refractive index value. Accordingly, the barrier layer may sufficiently cover components of the display panel and have superior encapsulation performance. For example, the display device may be capable of being manufactured using process steps simplified by the method for manufacturing the display device according to one or more embodiments, and due to the method, the display device may have superior reliability. In addition, if (e.g., when) the method for manufacturing the display device according to one or more embodiments includes the step (e.g., act or task) of forming the barrier layer including the inorganic polysilazane compound directly on an organic encapsulation film, the organic encapsulation film and the barrier layer may be formed through the same process method such as inkjet printing, so that the manufacture process is simplified, and also the display device has superior reliability.

The display device according to one or more embodiments may include the barrier layer including the inorganic polysilazane compound to have the high adhesion to the inorganic encapsulation layer so that the display panel is effectively protected to exhibit the superior reliability characteristics.

For example, the display device according to one or more embodiments may include the barrier layer, which includes the inorganic polysilazane compound, arranged directly on the inorganic encapsulation layer so that the barrier layer replaces the typical stacking structure of the organic encapsulation film and the upper inorganic encapsulation film. Accordingly, the manufacture process may be simplified, and also the light emitting elements vulnerable to oxygen, moisture, and/or the like may be effectively covered to exhibit the superior reliability characteristics. In addition, the display device according to one or more embodiments may include the barrier layer to provide the improved transmittance according to the reduction in thickness of the encapsulation layer.

In addition, the method for manufacturing the display device according to one or more embodiments may include the step (e.g., act or task) of providing the silazane resin composition on the inorganic encapsulation layer to form the barrier layer so that the silazane-based barrier layer having the sufficient thickness is formed. Accordingly, the display device with the superior reliability may be manufactured through the simplified process.

In other words, the present disclose provides a display device and a manufacturing method. The display device, in one or more embodiments, includes a barrier layer made of an inorganic polysilazane compound on an inorganic encapsulation layer, enhancing reliability thereof. If this barrier layer is directly applied to the inorganic encapsulation layer, it forms a strong bond, effectively protecting the display panel components. Additionally, incorporating an organic encapsulation film between the inorganic layer and the barrier layer can block moisture, oxygen, and chemicals, further safeguarding the display panel. The manufacturing method involves forming the barrier layer using a silazane resin composition applied via inkjet printing and cured with laser light, simplifying the process and reducing costs. This method ensures the barrier layer has sufficient thickness and high refractive index, providing excellent encapsulation performance. By using the same process for both the organic encapsulation film and the barrier layer, the manufacturing process is streamlined, resulting in a display device with superior reliability and improved transmittance due to the reduced thickness of the encapsulation layer.

In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

In the context of the present application and unless otherwise defined, the terms “use,” “using,” and “used” may be considered synonymous with the terms “utilize,” “utilizing,” and “utilized,” respectively.

As utilized herein, the terms “substantially,” “about,” “approximately,” or similar terms are used as terms of approximation and not as terms of degree, and are intended to account for the inherent deviations in measured or calculated values that would be recognized by those of ordinary skill in the art. “About” or “approximately” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” or “approximately” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The display device-manufacturing apparatus, the light emitting element, the display elements/devices, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although example embodiments of disclosure have been described, it is understood that the present disclosure should not be limited to these embodiments but one or more suitable changes and modifications can be made by one ordinary skilled in the art within the spirit and scope of the disclosure as hereinafter claimed.

Therefore, the technical scope of the disclosure is not limited to the contents described in the detailed description of the disclosure, but should be determined by the appended claims and equivalents thereof.

What is claimed is:

1. A display device, comprising:
a base layer;
a display element layer on the base layer and comprising a light emitting element;
an inorganic encapsulation film on the display element layer; and
a barrier layer on the inorganic encapsulation film and comprising an inorganic polysilazane compound.

2. The display device of claim 1, further comprising an organic encapsulation film between the inorganic encapsulation film and the barrier layer.

3. The display device of claim 1, wherein the barrier layer comprises an inorganic polymer layer comprising Si and N, or an inorganic polymer layer comprising Si, N, and O.

4. The display device of claim 1, wherein a refractive index of the barrier layer is in a range of about 1.53 to about 1.90.

5. The display device of claim 1, wherein a refractive index of the barrier layer gradually increases in a direction that is away from the inorganic encapsulation film.

6. The display device of claim 1, wherein the barrier layer has a thickness of about 1,000 Å to about 10,000 Å.

7. The display device of claim 6, wherein, when the thickness of the barrier layer is 3,000 Å or less, then the barrier layer is a silicon nitride layer or a silicon oxynitride layer.

8. The display device of claim 1, wherein,
the barrier layer comprises:
a first portion adjacent to the inorganic encapsulation film; and
a second portion spaced from the inorganic encapsulation film, and
a refractive index of the first portion is less than a refractive index of the second portion.

9. The display device of claim 8, wherein the first portion comprises a silazane-based compound having a repeating unit of Formula 1, and
the second portion comprises a silicon nitride or a silicon oxynitride: 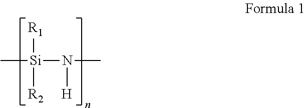
in Formula 1, R₁ and R₂ being each independently hydrogen, an alkyl group of 1 to 10 carbon atoms, or an aryl group of 6 to 30 ring-forming carbon atoms, and
n being an integer of 2 or more.

10. A display device, comprising:
a base layer;
a pixel defining film which is on the base layer, and in which a light emitting opening portion is defined;
a partition wall which is on the pixel defining film, and in which a partition wall opening portion overlapping the light emitting opening portion is defined;
a light emitting element overlapping the light emitting opening portion and the partition wall opening portion on a plane, and on the base layer;
an inorganic encapsulation pattern configured to cover the light emitting element; and
a barrier layer on the inorganic encapsulation pattern and comprising a polysilazane compound.

11. The display device of claim 10, wherein the inorganic encapsulation pattern has at least a portion on the partition wall, and covers a side surface of the partition wall, which defines the partition wall opening portion.

12. The display device of claim 10, further comprising a dummy pattern between the partition wall and the inorganic encapsulation pattern.

13. The display device of claim 10, wherein the light emitting element comprises:
a first electrode on the base layer;
a light emitting pattern on the first electrode; and
a second electrode on the light emitting pattern, the second electrode being electrically connected to the partition wall.

14. The display device of claim 10, wherein the partition wall comprises a first partition wall layer and a second partition wall layer, and
wherein,
the partition wall opening portion comprises:
a first region in which the light emitting element is arranged; and
a second region having a smaller width than the first region,
the first partition wall layer has a first inner side surface defining the first region, and
the second partition wall layer has a second inner side surface defining the second region.

15. The display device of claim 10, wherein the barrier layer comprises an inorganic polymer layer comprising Si and N, or an inorganic polymer layer comprising Si, N, and O, and
a refractive index of the barrier layer is in a range of about 1.53 to about 1.90.

16. The display device of claim 10, wherein the barrier layer is directly on the inorganic encapsulation pattern.

17. The display device of claim 10, wherein,
the barrier layer comprises:
a first portion adjacent to the inorganic encapsulation pattern; and
a second portion spaced apart from the inorganic encapsulation pattern,
a refractive index of the first portion is less than a refractive index of the second portion.

18. A method, the method comprising:
providing a base layer;
forming, on the base layer, a circuit layer comprising a conductive pattern and a plurality of insulation layers;
forming, on the circuit layer, a display element layer comprising a light emitting element;
forming an inorganic encapsulation layer that covers the light emitting element; and
forming a barrier layer on the inorganic encapsulation layer and comprising an inorganic polysilazane compound,
wherein the method is a method for manufacturing a display device.

19. The method of claim 18, wherein the forming of the barrier layer comprises:
providing a silazane resin composition through inkjet printing to form a preliminary barrier layer; and
emitting laser light onto the preliminary barrier layer to form the barrier layer in an N₂ atmosphere or an O₂ atmosphere.

20. The method of claim 19, wherein the silazane resin composition comprises a silazane compound comprising a repeating unit represented by Formula 1, and an organic solvent: 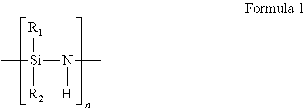
in Formula 1, R₁ and R₂ being each independently hydrogen, an alkyl group of 1 to 10 carbon atoms, or an aryl group of 6 to 30 ring-forming carbon atoms, and
n being an integer of 2 or more.
